(19) United States
(12) Patent Application Publication
(10) Pub. No.: US 2026/0293581 A1
(43) Pub. Date: Sep. 24, 2026

(54) SUBSTRATE PROCESSING APPARATUS AND METHOD FOR CONTROLLING SUBSTRATE PROCESSING APPARATUS

(71) Applicant: SCREEN Holdings Co., Ltd., Kyoto (JP)

(72) Inventor: Yoshinori TAWARATANI, Kyoto-shi (JP)

(21) Appl. No.: 19/564,787

(22) Filed: Mar. 12, 2026

(30) Foreign Application Priority Data
Mar. 21, 2025 (JP) 2025-046906

(51) Int. Cl. H10P 72/00

(52) U.S. Cl. CPC H10P 72/0448; H10P 72/0458; H10P 72/0604

(57) ABSTRACT

As a pre-filtration operation, a controller of a substrate processing apparatus causes, during a period from opening of a first intermediate valve to opening of a second intermediate valve, a filling pump to adjust a pressure of a treatment liquid in the filling pump so that a pressure value measured by a filling pressure sensor becomes a second supply pressure in a state where the first intermediate valve is opened, and an inlet valve, an outlet valve, and the second intermediate valve are closed, and after the first intermediate valve is opened, causes a discharge pump to adjust a pressure of the treatment liquid in the discharge pump so that a pressure value measured by a discharge pressure sensor becomes a third supply pressure in a state where the first intermediate valve is opened, and the inlet valve, the outlet valve, and the second intermediate valve are closed.

### CROSS-REFERENCE TO RELATED APPLICATIONS

This application claims priority to Japanese Patent Application No. 2025-046906 filed March 21, 2025, the subject matter of which is incorporated herein by reference in entirety.

### BACKGROUND

### Technical Field

The present invention relates to a substrate processing apparatus that processes a substrate and a method for controlling the substrate processing apparatus. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

A conventional substrate processing apparatus includes a nozzle, a pipe connected to the nozzle, and an upstream pump, a filter, and a downstream pump provided in the pipe (see, for example, JP 2019-044619 A). The filter is disposed between the upstream pump and the downstream pump. The upstream pump and the downstream pump are disposed close to each other.

JP 2022-138462 A discloses that a downstream pump is disposed away from an upstream pump. That is, the upstream pump is disposed near a treatment liquid bottle, whereas the downstream pump is disposed in a liquid treatment unit while being separated from the upstream pump.

JP 2007-005576 A discloses a substrate processing system including a pressurizing unit that pressurizes a bottle to pressure-feed a treatment liquid, a pump that stores the treatment liquid pressure-fed by the pressurizing unit inside, and a plurality of modules stacked on each other. The pump is disposed beside each of the plurality of modules.

### SUMMARY

Conventionally, reduction of particles in a treatment liquid (for example, resist) is an important problem. One of causes of particle generation is air bubbles in the treatment liquid. Gels are generated at an interface between air bubbles and a coating liquid (for example, resist), and the gels themselves become particles.

For example, when a filling pump (upstream pump) is disposed at a low position near a bottle and a discharge pump (downstream pump) is disposed at a high position near a processing chamber, air bubbles are likely to be generated due to a height difference therebetween.

When air bubbles are generated in the filling pump, the air bubbles and particles caused by the air bubbles are captured by a filter, but deterioration of the filter may be accelerated. In addition, when air bubbles are generated in the discharge pump, there is a possibility that a treatment liquid containing the air bubbles and particles caused by the air bubbles is discharged to a substrate. For example, when a treatment liquid containing air bubbles and particles caused by the air bubbles is applied to the substrate, the portion may be a defect.

The present invention has been made in view of such circumstances, and an object thereof is to provide a substrate processing apparatus capable of suppressing generation of air bubbles in a treatment liquid, and a method for controlling the substrate processing apparatus.

In order to achieve such an object, the present invention has the following configuration. That is, a substrate processing apparatus that processes a substrate, according to the present invention includes: a plurality of processing chambers stacked in a vertical direction; a liquid supply mechanism configured to supply a treatment liquid to at least one of the plurality of processing chambers; and a controller, in which each of the plurality of processing chambers includes a chuck configured to hold a substrate, and a nozzle configured to discharge the treatment liquid to the substrate held by the chuck, the liquid supply mechanism includes a feed pipe configured to supply the treatment liquid to a first nozzle that is the nozzle of a first processing chamber among the plurality of processing chambers, a filling pump provided in the feed pipe in a layer lower than the first processing chamber, a discharge pump provided in the feed pipe between the filling pump and the first nozzle in a layer same as the first processing chamber or in a layer higher than the first processing chamber, an inlet valve provided in the feed pipe at an upstream position of the filling pump, an outlet valve provided in the feed pipe between the discharge pump and the first nozzle, a filter provided in the feed pipe between the filling pump and the discharge pump, a first intermediate valve provided in the feed pipe between the filling pump and the filter, and a second intermediate valve provided in the feed pipe between the filter and the discharge pump, the filling pump includes a filling pressure sensor configured to measure a pressure of the treatment liquid in the filling pump, the discharge pump includes a discharge pressure sensor configured to measure a pressure of the treatment liquid in the discharge pump, the controller is configured to perform a pre-filtration operation and an actual filtration operation in this order, and as the pre-filtration operation, the controller is configured to cause the filling pump to adjust the pressure of the treatment liquid in the filling pump so that a pressure value measured by the filling pressure sensor becomes a first supply pressure in a state where the inlet valve, the outlet valve, the first intermediate valve, and the second intermediate valve are closed, push the treatment liquid to the second intermediate valve by opening the first intermediate valve when the pressure value measured by the filling pressure sensor reaches the first supply pressure, during a period from the opening of the first intermediate valve to opening of the second intermediate valve, cause the filling pump to adjust the pressure of the treatment liquid in the filling pump so that the pressure value measured by the filling pressure sensor becomes a second supply pressure in a state where the inlet valve and the second intermediate valve are closed, after the first intermediate valve is opened, cause the discharge pump to adjust the pressure of the treatment liquid in the discharge pump so that a pressure value measured by the discharge pressure sensor becomes a third supply pressure in a state where the outlet valve and the second intermediate valve are closed, and open the second intermediate valve when the pressure value measured by the discharge pressure sensor reaches the third supply pressure, and as the actual filtration operation, the controller is configured to cause the treatment liquid to be sent from the filling pump toward the discharge pump in a state where the inlet valve and the outlet valve are closed.

According to the substrate processing apparatus of the present invention, the pre-filtration operation that is a preparation operation of the actual filtration operation is performed before the actual filtration operation. In the pre-filtration operation, when each of the first intermediate valve and the second intermediate valve is opened, the pressure of the treatment liquid in the filling pump may be greatly reduced. According to the present invention, during the period from the opening of the first intermediate valve to the opening of the second intermediate valve, the filling pump is caused to adjust the pressure of the treatment liquid in the filling pump so that the pressure value measured by the filling pressure sensor becomes the second supply pressure in a state where the first intermediate valve is opened, and the inlet valve, the outlet valve, and the second intermediate valve are closed. Therefore, even when the first intermediate valve is opened, it is possible to suppress a large decrease in the pressure of the treatment liquid in the filling pump.

According to the present invention, after the first intermediate valve is opened, the discharge pump is caused to adjust the pressure of the treatment liquid in the discharge pump so that the pressure value measured by the discharge pressure sensor becomes the predetermined third supply pressure in a state where the first intermediate valve is opened, and the inlet valve, the outlet valve, and the second intermediate valve are closed. As a result, the pressures of the treatment liquid on an inflow side and an outflow side of the second intermediate valve become substantially the same. Even when the second intermediate valve is opened, it is possible to suppress a large decrease in the pressure of the treatment liquid in the filling pump. As a result, generation of air bubbles in the treatment liquid can be suppressed.

Further, in the substrate processing apparatus described above, it is preferable that the liquid supply mechanism further includes a return pipe configured to connect the discharge pump and a return position in the feed pipe between the first intermediate valve and the inlet valve, and a purge valve provided in the return pipe, and as a purge operation, the controller is configured to open the inlet valve in a state where the first intermediate valve and the purge valve are closed to release the treatment liquid in the filling pump to an upstream side of atmospheric pressure of the inlet valve, close the inlet valve after a preset time has elapsed since the opening of the inlet valve so that the pressure value measured by the discharge pressure sensor does not become a negative pressure when the purge valve is opened, after closing the inlet valve, perform a purge valve opening operation to open the purge valve in a state where the outlet valve, the first intermediate valve, and the second intermediate valve are closed, and after opening the purge valve, perform an actual purge operation to cause the filling pump and the discharge pump to return the treatment liquid from the discharge pump toward the filling pump through the return pipe in a state where the purge valve is opened and the inlet valve, the outlet valve, the first intermediate valve, and the second intermediate valve are closed.

The substrate processing apparatus according to the present invention performs the purge operation. In the purge operation, when the inlet valve and the purge valve are opened, the treatment liquid in the discharge pump is pulled toward the filling pump due to a height difference between the filling pump and the discharge pump, and as a result, the pressure of the treatment liquid in the discharge pump may become a negative pressure. According to the present invention, the inlet valve is closed after a preset time has elapsed since the opening of the inlet valve so that the pressure value measured by the discharge pressure sensor does not become a negative pressure when the purge valve is opened. Therefore, even when the purge valve is opened, it is possible to suppress the pressure of the treatment liquid in the discharge pump from becoming a negative pressure, and as a result, generation of air bubbles in the treatment liquid can be suppressed.

Further, in the substrate processing apparatus described above, it is preferable that as the purge operation, the controller is configured to, after closing the inlet valve and before opening the purge valve, cause the discharge pump to start pushing the treatment liquid from the discharge pump toward the purge valve through the return pipe in a state where the outlet valve, the second intermediate valve, and the purge valve are closed, and as the purge valve opening operation of the purge operation, the controller is configured to open the purge valve in a state where the inlet valve, the outlet valve, the first intermediate valve, and the second intermediate valve are closed, after a preset time has elapsed since the start of pushing of the treatment liquid through the return pipe.

Before the purge valve is opened, the treatment liquid starts to be pushed toward the purge valve. That is, the pressure of the treatment liquid in the discharge pump is increased. Therefore, it is possible to further suppress the treatment liquid in the discharge pump from having a negative pressure when the purge valve is opened. In addition, the pressure in the discharge pump can be relatively gently reduced.

Further, in the substrate processing apparatus described above, it is preferable that as the purge operation, the controller is configured to, after closing the inlet valve and before opening the purge valve, cause the discharge pump to adjust the pressure of the treatment liquid in the discharge pump so that the pressure value measured by the discharge pressure sensor becomes a first purge pressure in a state where the outlet valve, the second intermediate valve, and the purge valve are closed, as the purge valve opening operation of the purge operation, the controller is configured to open the purge valve in a state where the inlet valve, the outlet valve, the first intermediate valve, and the second intermediate valve are closed, when the pressure value measured by the discharge pressure sensor reaches the first purge pressure, as the purge operation, the controller is configured to, after opening the purge valve, cause the discharge pump to adjust the pressure of the treatment liquid in the discharge pump so that the pressure value measured by the discharge pressure sensor becomes a second purge pressure in a state where the inlet valve, the outlet valve, the first intermediate valve, and the second intermediate valve are closed, and as the actual purge operation of the purge operation, the controller is configured to when the pressure value measured by the discharge pressure sensor reaches the second purge pressure, cause the filling pump and the discharge pump to return the treatment liquid from the discharge pump toward the filling pump through the return pipe so that the pressure value measured by the discharge pressure sensor maintains the second purge pressure, in a state where the purge valve is opened, and the inlet valve, the outlet valve, the first intermediate valve, and the second intermediate valve are closed.

Before the purge valve is opened, the discharge pump adjusts the pressure of the treatment liquid in the discharge pump so that the pressure value measured by the discharge pressure sensor becomes the first purge pressure. After the purge valve is opened, the discharge pump adjusts the pressure of the treatment liquid in the discharge pump so that the pressure value measured by the discharge pressure sensor becomes the second purge pressure. That is, the pressure of the treatment liquid is adjusted before and after the opening operation of the purge valve. Therefore, it is possible to further suppress the treatment liquid in the discharge pump from having a negative pressure when the purge valve is opened. In addition, the pressure in the discharge pump can be relatively gently reduced.

Further, in the substrate processing apparatus described above, it is preferable that the first intermediate valve, the second intermediate valve, and the filter are each disposed in the layer same as the first processing chamber or in the layer higher than the first processing chamber. For example, by disposing the filter in the same layer as the discharge pump, that is, near the discharge pump, a distance between the filter and the first nozzle can be shortened.

In the substrate processing apparatus described above, it is preferable that the purge valve and the return position are each disposed in the layer same as the first processing chamber or in the layer higher than the first processing chamber. For example, the return pipe can be relatively short. Therefore, the treatment liquid can be discharged from the return pipe relatively quickly.

Further, in the substrate processing apparatus described above, it is preferable that the filling pump includes a first storage space configured to store the treatment liquid, a first volume changing member configured to change a volume of the first storage space, and a first pump drive mechanism configured to perform a pump operation by operating the first volume changing member, the filling pressure sensor is configured to measure a pressure of the treatment liquid in the first storage space, the discharge pump includes a second storage space configured to store the treatment liquid, a second volume changing member configured to change a volume of the second storage space, and a second pump drive mechanism configured to perform a pump operation by operating the second volume changing member, and the discharge pressure sensor is configured to measure the pressure of the treatment liquid in the second storage space.

Further, a substrate processing apparatus that processes a substrate, according to the present invention includes: a plurality of processing chambers stacked in a vertical direction; a liquid supply mechanism configured to supply a treatment liquid to at least one of the plurality of processing chambers; and a controller, in which each of the plurality of processing chambers includes a chuck configured to hold a substrate, and a nozzle configured to discharge the treatment liquid to the substrate held by the chuck, the liquid supply mechanism includes a feed pipe configured to supply the treatment liquid to a first nozzle that is the nozzle of a first processing chamber among the plurality of processing chambers, a filling pump provided in the feed pipe in a layer lower than the first processing chamber, a discharge pump provided in the feed pipe between the filling pump and the first nozzle in a layer same as the first processing chamber or in a layer higher than the first processing chamber, an inlet valve provided in the feed pipe at an upstream position of the filling pump, an outlet valve provided in the feed pipe between the discharge pump and the first nozzle, a first intermediate valve provided in the feed pipe between the filling pump and the discharge pump, a return pipe configured to connect the discharge pump and a return position in the feed pipe between the first intermediate valve and the inlet valve, and a purge valve provided in the return pipe, the filling pump includes a filling pressure sensor configured to measure a pressure of the treatment liquid in the filling pump, the discharge pump includes a discharge pressure sensor configured to measure a pressure of the treatment liquid in the discharge pump, and as a purge operation, the controller is configured to open the inlet valve in a state where the outlet valve, the first intermediate valve, and the purge valve are closed to release the treatment liquid in the filling pump to an upstream side of atmospheric pressure of the inlet valve, close the inlet valve after a preset time has elapsed since the opening of the inlet valve so that a pressure value measured by the discharge pressure sensor does not become a negative pressure when the purge valve is opened, after closing the inlet valve, perform a purge valve opening operation to open the purge valve in a state where the outlet valve and the first intermediate valve are closed, and after opening the purge valve, perform an actual purge operation to cause the treatment liquid to be returned from the discharge pump toward the filling pump through the return pipe in a state where the outlet valve and the first intermediate valve are closed.

In a method for controlling a substrate processing apparatus that processes a substrate, according to the present invention, the substrate processing apparatus including a plurality of processing chambers stacked in a vertical direction, and a liquid supply mechanism configured to supply a treatment liquid to at least one of the plurality of processing chambers, each of the plurality of processing chambers including a chuck configured to hold a substrate, and a nozzle configured to discharge the treatment liquid to the substrate held by the chuck, the liquid supply mechanism including a feed pipe configured to supply the treatment liquid to a first nozzle that is the nozzle of a first processing chamber among the plurality of processing chambers, a filling pump provided in the feed pipe in a layer lower than the first processing chamber, a discharge pump provided in the feed pipe between the filling pump and the first nozzle in a layer same as the first processing chamber or in a layer higher than the first processing chamber, an inlet valve provided in the feed pipe at an upstream position of the filling pump, an outlet valve provided in the feed pipe between the discharge pump and the first nozzle, a filter provided in the feed pipe between the filling pump and the discharge pump, a first intermediate valve provided in the feed pipe between the filling pump and the filter, and a second intermediate valve provided in the feed pipe between the filter and the discharge pump, the filling pump including a filling pressure sensor configured to measure a pressure of the treatment liquid in the filling pump, and the discharge pump including a discharge pressure sensor configured to measure a pressure of the treatment liquid in the discharge pump, the method includes: as a pre-filtration operation, causing the filling pump to adjust the pressure of the treatment liquid in the filling pump so that a pressure value measured by the filling pressure sensor becomes a first supply pressure in a state where the inlet valve, the outlet valve, the first intermediate valve, and the second intermediate valve are closed; pushing the treatment liquid to the second intermediate valve by opening the first intermediate valve when the pressure value measured by the filling pressure sensor reaches the first supply pressure; during a period from the opening of the first intermediate valve to opening of the second intermediate valve, causing the filling pump to adjust the pressure of the treatment liquid in the filling pump so that the pressure value measured by the filling pressure sensor becomes a second supply pressure in a state where the inlet valve and the second intermediate valve are closed; after the first intermediate valve is opened, causing the discharge pump to adjust the pressure of the treatment liquid in the discharge pump so that a pressure value measured by the discharge pressure sensor becomes a third supply pressure in a state where the outlet valve and the second intermediate valve are closed; and opening the second intermediate valve when the pressure value measured by the discharge pressure sensor reaches the third supply pressure, and the method further includes, as an actual filtration operation after the pre-filtration operation, causing the treatment liquid to be sent from the filling pump toward the discharge pump in a state where the inlet valve and the outlet valve are closed.

In a method for controlling a substrate processing apparatus that processes a substrate, according to the present invention, the substrate processing apparatus including a plurality of processing chambers stacked in a vertical direction, and a liquid supply mechanism configured to supply a treatment liquid to at least one of the plurality of processing chambers, each of the plurality of processing chambers including a chuck configured to hold a substrate, and a nozzle configured to discharge the treatment liquid to the substrate held by the chuck, the liquid supply mechanism including a feed pipe configured to supply the treatment liquid to a first nozzle that is the nozzle of a first processing chamber among the plurality of processing chambers, a filling pump provided in the feed pipe in a layer lower than the first processing chamber, a discharge pump provided in the feed pipe between the filling pump and the first nozzle in a layer same as the first processing chamber or in a layer higher than the first processing chamber, an inlet valve provided in the feed pipe at an upstream position of the filling pump, an outlet valve provided in the feed pipe between the discharge pump and the first nozzle, a first intermediate valve provided in the feed pipe between the filling pump and the discharge pump, a return pipe configured to connect the discharge pump and a return position in the feed pipe between the first intermediate valve and the inlet valve, and a purge valve provided in the return pipe, the filling pump including a filling pressure sensor configured to measure a pressure of the treatment liquid in the filling pump, and the discharge pump including a discharge pressure sensor configured to measure a pressure of the treatment liquid in the discharge pump, the method includes: as a purge operation, opening the inlet valve in a state where the outlet valve, the first intermediate valve, and the purge valve are closed to release the treatment liquid in the filling pump to an upstream side of atmospheric pressure of the inlet valve; closing the inlet valve after a preset time has elapsed since the opening of the inlet valve so that a pressure value measured by the discharge pressure sensor does not become a negative pressure when the purge valve is opened; after closing the inlet valve, performing a purge valve opening operation to open the purge valve in a state where the outlet valve and the first intermediate valve are closed; and after opening the purge valve, performing an actual purge operation to cause the treatment liquid to be returned from the discharge pump toward the filling pump through the return pipe in a state where the outlet valve and the first intermediate valve are closed.

According to a substrate processing apparatus and a method for controlling the substrate processing apparatus according to the present invention, generation of air bubbles in a treatment liquid can be suppressed.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a side view showing a schematic configuration of a substrate processing apparatus according to a first embodiment;

FIG. 2 is a piping diagram of the substrate processing apparatus;

FIG. 3 is a side view showing a schematic configuration of a first pump mechanism;

FIG. 4 is a block diagram for describing a configuration related to control;

FIG. 5 is a flowchart for describing an operation of the first pump mechanism;

FIG. 6A is a diagram showing a ready operation, FIG. 6B is a diagram showing a discharge operation, FIG. 6C is a diagram showing a filtration operation, FIG. 6D is a diagram showing a purge operation, and FIG. 6E is a diagram showing a filling operation;

FIG. 7 is a diagram for describing the filtration operation (a pre-filtration operation and an actual filtration operation);

FIG. 8 is a diagram for describing a change in a pressure value measured by each of a filling pressure sensor and a discharge pressure sensor;

FIG. 9 is a diagram for describing a purge operation according to a second embodiment;

FIG. 10 is a diagram for describing a change in a pressure value measured by each of a filling pressure sensor and a discharge pressure sensor according to the second embodiment;

FIG. 11 is a diagram for describing a purge operation according to a third embodiment; and

FIG. 12 is a diagram for describing a change in a pressure value measured by each of a filling pressure sensor and a discharge pressure sensor according to the third embodiment.

### DETAILED DESCRIPTION

Hereinafter, embodiments of the present invention will be described.

### First embodiment

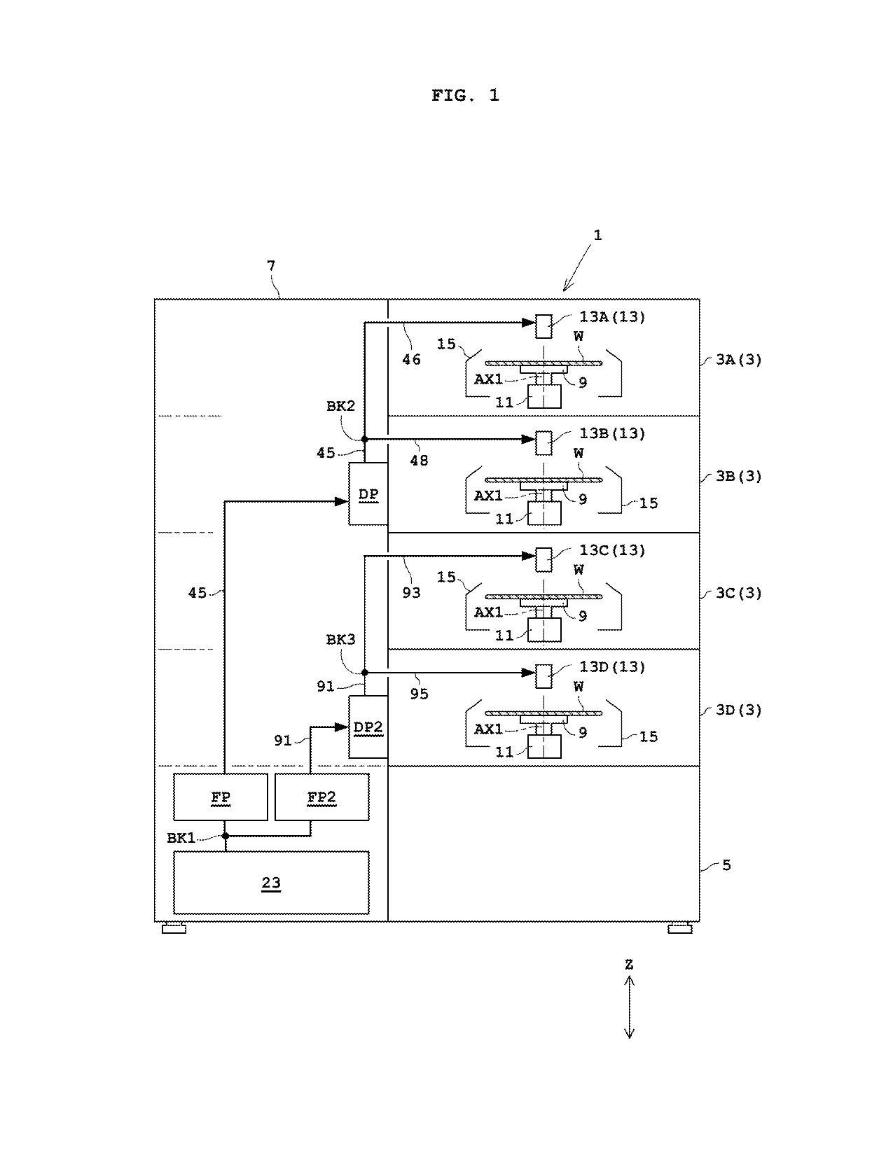

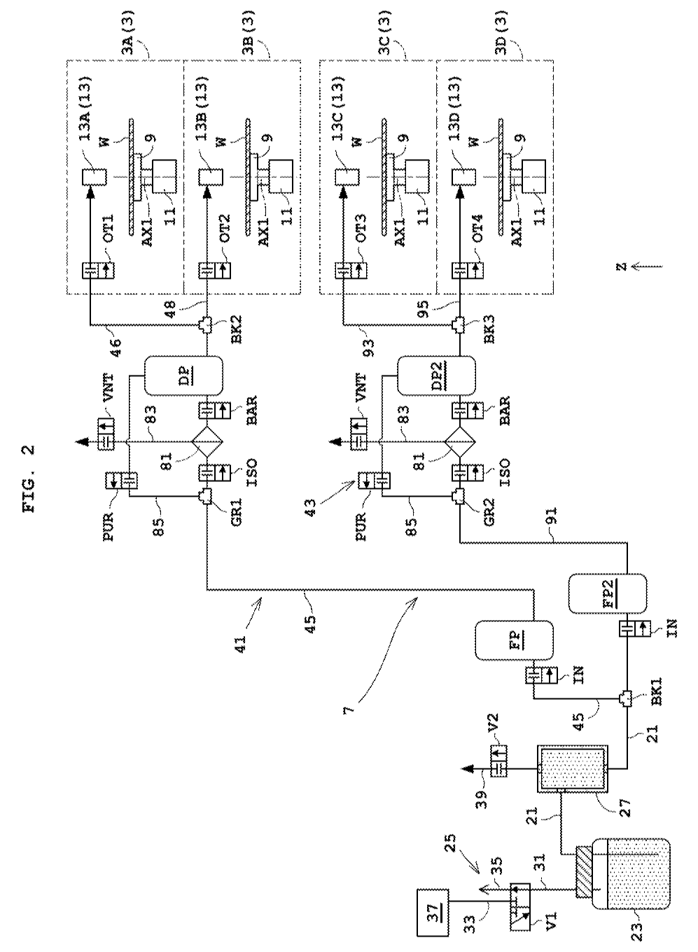

Hereinafter, a first embodiment of the present invention will be described with reference to the drawings. FIG. 1 is a side view showing a schematic configuration of a substrate processing apparatus 1 according to the first embodiment. FIG. 2 is a piping diagram of the substrate processing apparatus 1.

### 1. Configuration of substrate processing apparatus

Reference is made to FIG. 1. The substrate processing apparatus 1 processes a substrate W. The substrate W is formed in, for example, a disk shape. The substrate processing apparatus 1 includes a plurality of processing chambers 3, a housing casing 5, and a liquid supply mechanism 7. In the present embodiment, the substrate processing apparatus 1 includes, for example, four processing chambers 3A, 3B, 3C, and 3D. When the processing chambers 3A to 3D are not distinguished, the processing chambers 3A to 3D are referred to as “processing chambers 3”.

The plurality of (for example, four) processing chambers 3 are stacked in a vertical direction Z. When the housing casing 5 is included, the plurality of (for example, four) processing chambers 3 and the housing casing 5 are stacked in the vertical direction Z. The four processing chambers 3 and the housing casing 5 form five layers.

The processing chamber 3A is disposed in the uppermost layer that is the highest layer. The processing chamber 3B is disposed one layer below the processing chamber 3A. In other words, the processing chamber 3B is disposed in the layer lower than the processing chamber 3A. The processing chamber 3C is disposed one layer below the processing chamber 3B. The processing chamber 3D is disposed one layer below the processing chamber 3C.

The housing casing 5 is disposed in a layer lower than the four processing chambers 3A to 3D. That is, the housing casing 5 is disposed one layer below the processing chamber 3D disposed in the lowest layer among the four processing chambers 3A to 3D. Note that, in the housing casing 5, for example, a drainage pipe for sending a treatment liquid collected by a cup 15 to be described later is provided, but the housing casing 5 may be empty.

### 1-1. Each processing chamber

Each of the four processing chambers 3 includes a spin chuck 9, a rotation mechanism 11, a nozzle 13, and the cup 15. For example, the processing chamber 3B is configured similarly to each of the three processing chambers 3A, 3C, and 3D. Therefore, the spin chuck 9, the rotation mechanism 11, the nozzle 13, and the cup 15 of the processing chamber 3B will be described.

The spin chuck 9 holds the substrate W in a horizontal posture. The spin chuck 9 is, for example, a vacuum chuck, but is not limited thereto. The vacuum chuck is configured to hold a central portion of a lower surface of the substrate W by vacuum suction by a pump, for example.

The rotation mechanism 11 includes, for example, an electric motor. The rotation mechanism 11 rotates the substrate W about a vertical axis AX1 via the spin chuck 9. In other words, the rotation mechanism 11 rotates the spin chuck 9 holding the substrate W about the vertical axis AX1. The vertical axis AX1 passes through the center of the substrate W held by the spin chuck 9.

The nozzle 13 discharges a treatment liquid to the substrate W held by the spin chuck 9. The cup 15 surrounds a side of the substrate W held by the spin chuck 9. The cup 15 collects the treatment liquid scattered from the rotating substrate W. When the four nozzles 13 of the four processing chambers 3A to 3D are distinguished, the four nozzles 13 are referred to as four nozzles 13A, 13B, 13C, and 13D.

### 1-2. Liquid supply mechanism

Reference is made to FIGS. 1 and 2. The liquid supply mechanism 7 supplies the treatment liquid to at least one of the plurality of (for example, four) processing chambers 3. In the present embodiment, the liquid supply mechanism 7 selectively supplies the treatment liquid to each of the four processing chambers 3.

The liquid supply mechanism 7 is disposed on a side of the four processing chambers 3 and the housing casing 5. That is, the liquid supply mechanism 7, and the four processing chambers 3 and the housing casing 5, are disposed in a horizontal direction. The liquid supply mechanism 7 includes a common pipe 21, a treatment liquid bottle 23, a gas supply mechanism 25, a trap tank 27, and a first branch pipe BK1.

A base end of the common pipe 21 is inserted into the treatment liquid bottle 23. A distal end of the common pipe 21 is connected to the first branch pipe BK1. The treatment liquid bottle 23 stores the treatment liquid. As the treatment liquid, for example, a resist liquid such as a photoresist liquid, a coating liquid for forming an antireflection film, a solvent (for example, thinner), a rinse liquid, a developer, or an etching liquid is used. As the rinse liquid, for example, deionized water (DIW) is used.

The gas supply mechanism 25 is configured to supply gas to the treatment liquid bottle 23 and to open an inside of the treatment liquid bottle 23 to the atmosphere. The gas supply mechanism 25 includes two gas pipes 31 and 33, a vent pipe 35, and a three-way valve V1.

A distal end of the gas pipe 31 is connected to the treatment liquid bottle 23, and a base end of the gas pipe 31 is connected to the three-way valve V1. A distal end of the gas pipe 33 is connected to the three-way valve V1, and a base end of the gas pipe 33 is connected to a gas supply source 37. The gas supply source 37 supplies gas into the treatment liquid bottle 23 via the two gas pipes 31 and 33 and the three-way valve V1. As the gas, for example, an inert gas such as nitrogen is used. A distal end of the vent pipe 35 is connected to the three-way valve V1, and the other end of the vent pipe 35 is opened to the atmosphere.

The three-way valve V1 selectively connects the gas pipe 31 to one of the gas pipe 33 and the vent pipe 35. The three-way valve V1 normally connects the gas pipe 31 and the vent pipe 35. As a result, the inside of the treatment liquid bottle 23 becomes atmospheric pressure. The three-way valve V1 connects the two gas pipes 31 and 33. As a result, the treatment liquid stored in the treatment liquid bottle 23 can be sent out to the common pipe 21.

The trap tank 27 is provided in the common pipe 21 between the treatment liquid bottle 23 and the first branch pipe BK1. The trap tank 27 can store the treatment liquid sent from the treatment liquid bottle 23 in the trap tank 27. The trap tank 27 is configured to detect the remaining amount of the treatment liquid in the trap tank 27 by a liquid level sensor (not shown).

One end of a vent pipe 39 is connected to a ceiling of the trap tank 27. The vent pipe 39 is provided with a vent valve V2. For example, the liquid supply mechanism 7 sends the treatment liquid from the treatment liquid bottle 23 to the trap tank 27 in a state where the vent valve V2 is opened and two inlet valves IN (to be described later) are closed. As a result, the treatment liquid containing air bubbles in the trap tank 27 is discharged through the vent pipe 39.

### 1-2-1. Two pump mechanisms

The liquid supply mechanism 7 includes, for example, a first pump mechanism 41 and a second pump mechanism 43. The first pump mechanism 41 supplies the treatment liquid to the upper two processing chambers 3A and 3B. The second pump mechanism 43 supplies the treatment liquid to the lower two processing chambers 3C and 3D. First, the first pump mechanism 41 will be described.

### 1-2-2. First pump mechanism

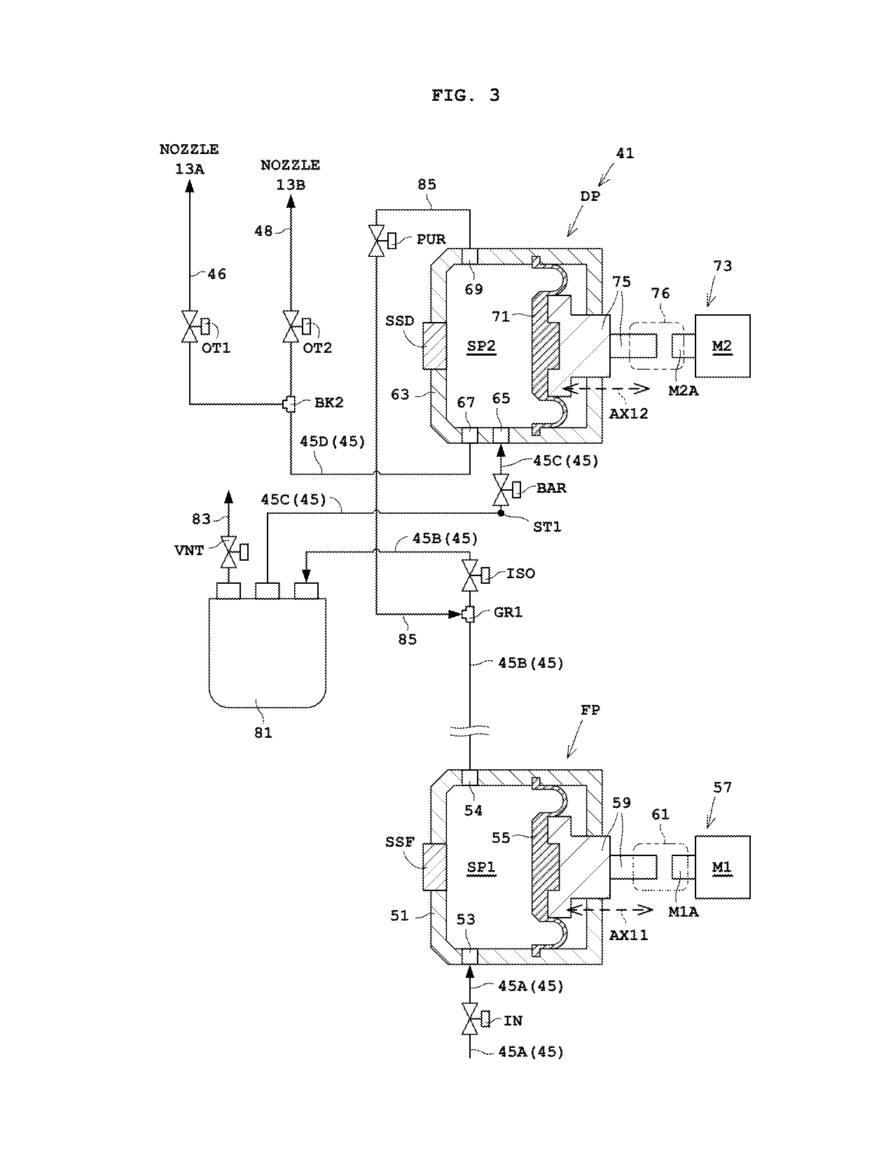

Reference is made to FIGS. 2 and 3. FIG. 3 is a side view showing a schematic configuration of the first pump mechanism 41. The first pump mechanism 41 includes a feed pipe 45 and a second branch pipe BK2, and includes, for example, two sub-branch pipes 46 and 48. A base end of the feed pipe 45 is connected to the first branch pipe BK1, and a distal end of the feed pipe 45 is connected to the second branch pipe BK2.

A base end of each of the two sub-branch pipes 46 and 48 is connected to the second branch pipe BK2. A distal end of the sub-branch pipe 46 is connected to the nozzle 13A of the processing chamber 3A. Similarly, a distal end of the sub-branch pipe 48 is connected to the nozzle 13B of the processing chamber 3B. For example, the feed pipe 45 and the sub-branch pipe 48 supply the treatment liquid to the nozzle 13B of the processing chamber 3B among the four processing chambers 3A to 3D.

The first pump mechanism 41 further includes a filling pump FP and a discharge pump DP. The filling pump FP is provided in the feed pipe 45 between the first branch pipe BK1 and the second branch pipe BK2. In other words, as shown in FIG. 1, the filling pump FP is provided in the feed pipe 45 in the same layer as the housing casing 5, which is the layer lower than the processing chamber 3B, for example.

The discharge pump DP is provided in the feed pipe 45 between the filling pump FP and the second branch pipe BK2. In other words, as shown in FIG. 1, the discharge pump DP is provided in the feed pipe 45 between the filling pump FP and the nozzle 13B of the processing chamber 3B, for example, in the same layer as the processing chamber 3B. In other words, the discharge pump DP is provided on a side surface of the processing chamber 3B. The discharge pump DP is disposed downstream of the filling pump FP and is disposed at a position higher than the filling pump FP.

As shown in FIG. 3, the feed pipe 45 includes four pipes 45A, 45B, 45C, and 45D. The filling pump FP is provided between the two pipes 45A and 45B. The discharge pump DP is provided between the two pipes 45C and 45D. A base end of the pipe 45A is connected to the first branch pipe BK1. A distal end of the pipe 45D is connected to the second branch pipe BK2.

The filling pump FP includes a casing 51, an inlet 53, an outlet 54, a diaphragm 55, a pump drive mechanism 57, and a filling pressure sensor SSF. A storage space SP1 is provided inside the casing 51. The treatment liquid is stored in the storage space SP1. The inlet 53 and the outlet 54 are each provided on a wall of the casing 51 and communicate with the storage space SP1. A distal end of the pipe 45A is connected to the inlet 53, and a base end of the pipe 45B is connected to the outlet 54.

The diaphragm 55 (volume changing member) changes a volume of the storage space SP1. A peripheral edge portion of the diaphragm 55 is fixed to an inner wall of the casing 51. For example, a rolling diaphragm is used as each of the diaphragm 55 and a diaphragm 71 to be described later. The pump drive mechanism 57 operates (deforms) the diaphragm 55 to perform a pump operation. The pump drive mechanism 57 includes a first rod 59, a conversion mechanism 61, and an electric motor M1.

A distal end of the first rod 59 is coupled to a central portion of the diaphragm 55. A base end portion of the first rod 59 is coupled to a rotation output shaft M1A of the electric motor M1 via the conversion mechanism 61. The conversion mechanism 61 and a conversion mechanism 76 to be described later include, for example, two or more gears or a screw shaft and a nut. The conversion mechanism 61 converts rotation of the rotation output shaft M1A of the electric motor M1 into linear movement in an axial direction AX11 of the first rod 59. Therefore, the central portion of the diaphragm 55 advances and retreats in the axial direction AX11.

As a result, the diaphragm 55 is deformed, and the volume of the storage space SP1 in the casing 51 is changed. Further, by advancing the central portion of the diaphragm 55, a pressure of the treatment liquid in at least the storage space SP1 can be increased. In addition, by retreating the central portion of the diaphragm 55, the pressure of the treatment liquid in at least the storage space SP1 can be lowered.

The filling pressure sensor SSF is provided on the inner wall of the casing 51. For example, the filling pressure sensor SSF is disposed so as to face the diaphragm 55. The filling pressure sensor SSF measures the pressure of the treatment liquid in the filling pump FP, that is, in the storage space SP1.

The discharge pump DP is configured similarly to the filling pump FP. The discharge pump DP includes a casing 63, an inlet 65, an outlet 67, a return outlet 69, a diaphragm 71, a pump drive mechanism 73, and a discharge pressure sensor SSD. The treatment liquid is stored in a storage space SP2 of the casing 51. The inlet 65, the outlet 67 and the return outlet 69 are each provided on a wall of the casing 63 and communicate with the storage space SP2. A distal end of the pipe 45C is connected to the inlet 65, and a base end of the pipe 45D is connected to the outlet 67. A base end of a return pipe 85 to be described later is connected to the return outlet 69.

The diaphragm 71 (volume changing member) changes a volume of the storage space SP2. A peripheral edge portion of the diaphragm 71 is fixed to an inner wall of the casing 63. The pump drive mechanism 73 operates (deforms) the diaphragm 71 to perform a pump operation. The pump drive mechanism 73 includes a second rod 75, a conversion mechanism 76, and an electric motor M2.

A distal end of the second rod 75 is coupled to a central portion of the diaphragm 71. A base end portion of the second rod 75 is coupled to a rotation output shaft M2A of the electric motor M2 via the conversion mechanism 76. The conversion mechanism 76 converts rotation of the rotation output shaft M2A of the electric motor M2 into linear movement in an axial direction AX12 of the second rod 75. Therefore, the central portion of the diaphragm 71 advances and retreats in the axial direction AX12.

As a result, the diaphragm 71 is deformed, and the volume of the storage space SP2 in the casing 63 is changed. Further, by advancing the central portion of the diaphragm 71, a pressure of the treatment liquid in at least the storage space SP2 can be increased. In addition, by retreating the central portion of the diaphragm 71, the pressure of the treatment liquid in at least the storage space SP2 can be lowered.

The discharge pressure sensor SSD is provided on the inner wall of the casing 63. For example, the discharge pressure sensor SSD is disposed so as to face the diaphragm 71. The discharge pressure sensor SSD measures the pressure of the treatment liquid in the discharge pump DP, that is, in the storage space SP2.

The first pump mechanism 41 further includes a filter 81, a vent pipe 83, and a vent valve VNT. The filter 81 is provided in the feed pipe 45 between the filling pump FP and the discharge pump DP. Specifically, as shown in FIG. 3, the filter 81 is disposed between the two pipes 45B and 45C. The filter 81 filters the treatment liquid. As a result, air bubbles and particles in the treatment liquid are captured.

In the filter 81, a distal end of the pipe 45B is connected, and a base end of the pipe 45C is connected. Air bubbles and particles in the treatment liquid sent from the pipe 45B are captured by a filter body in the filter 81, and the treatment liquid from which the air bubbles and the like have been removed is sent to the pipe 45C. The vent pipe 83 is connected to the filter 81. The vent pipe 83 is provided with the vent valve VNT. By opening the vent valve VNT, air bubbles and the like before passing through the filter body in the filter 81 can be discharged through the vent pipe 83.

The first pump mechanism 41 further includes the inlet valve IN, a first intermediate valve ISO, a second intermediate valve BAR, and two outlet valves OT1 and OT2. The inlet valve IN is provided in the feed pipe 45 (pipe 45A) at an upstream position of the filling pump FP. The first intermediate valve ISO is provided in the feed pipe 45 (pipe 45B) between the filling pump FP and the filter 81. The second intermediate valve BAR is provided in the feed pipe 45 (pipe 45C) between the filter 81 and the discharge pump DP.

The outlet valve OT1 is provided in the sub-branch pipe 46 between the discharge pump DP and the nozzle 13A of the processing chamber 3A. The outlet valve OT2 is provided in the sub-branch pipe 48 between the discharge pump DP and the nozzle 13B of the processing chamber 3B.

The first pump mechanism 41 further includes the return pipe 85, a first merging pipe GR1, and a purge valve PUR. The return pipe 85 connects the discharge pump DP and a return position in the feed pipe 45 between the first intermediate valve ISO and the inlet valve IN. The return position may be in the feed pipe 45 between the first intermediate valve ISO and the filling pump FP. The return position is the first merging pipe GR1. The first merging pipe GR1 is provided in the pipe 45B. The base end of the return pipe 85 is connected to the return outlet 69 of the discharge pump DP, and a distal end of the return pipe 85 is connected to the first merging pipe GR1. The purge valve PUR is provided in the return pipe 85.

### 1-2-3. Height relationship

Reference is made to FIGS. 1 and 2. The common pipe 21, the treatment liquid bottle 23, the trap tank 27, and the first branch pipe BK1 are disposed in the same layer as the housing casing 5. The filling pump FP and the inlet valve IN of the first pump mechanism 41 are also disposed in the same layer as the housing casing 5. The feed pipe 45 is disposed from the same layer as the housing casing 5 to the same layer as the processing chamber 3B.

In the first pump mechanism 41, the first merging pipe GR1, the first intermediate valve ISO, the filter 81, the second intermediate valve BAR, the discharge pump DP, the second branch pipe BK2, the sub-branch pipe 48, the return pipe 85, and the purge valve PUR are disposed in the same layer as the processing chamber 3B. The sub-branch pipe 46 is disposed from the same layer as the processing chamber 3B to the same layer as the processing chamber 3A. The outlet valve OT1 is disposed inside the uppermost processing chamber 3A. The outlet valve OT2 is disposed inside the processing chamber 3B. The outlet valve OT2 may be disposed outside the processing chamber 3B. In this regard, the outlet valve OT1 is similar.

In the first pump mechanism 41, at least one of the first merging pipe GR1, the first intermediate valve ISO, the filter 81, the second intermediate valve BAR, the discharge pump DP, the second branch pipe BK2, the return pipe 85, and the purge valve PUR may be provided in the same layer as the processing chamber 3A, or may be provided at a boundary between the two processing chambers 3A and 3B.

In the first pump mechanism 41, each of the second intermediate valve BAR and the filter 81 is disposed adjacent to the discharge pump DP. The filter 81 may be disposed adjacent to the second intermediate valve BAR. The first intermediate valve ISO may be disposed adjacent to at least one of the second intermediate valve BAR and the filter 81. The first merging pipe GR1 may be disposed adjacent to the first intermediate valve ISO.

By disposing the filter 81 in the same layer as the discharge pump DP, that is, near the discharge pump DP, a distance between the filter 81 and the nozzle 13 can be shortened. As a result, it is possible to suppress particles generated downstream of the filter 81 from being discharged from the nozzle 13. By disposing the first intermediate valve ISO in the same layer as the discharge pump DP, that is, near the discharge pump DP, the first merging pipe GR1 can be located close to the discharge pump DP. Therefore, the return pipe 85 can be relatively short. Therefore, the treatment liquid can be discharged from the return pipe 85 relatively quickly.

### 1-2-4. Second pump mechanism

A configuration of the second pump mechanism 43 is largely common with that of the first pump mechanism 41. Therefore, a part of description common to the first pump mechanism 41 is omitted.

The second pump mechanism 43 includes a feed pipe 91 and a third branch pipe BK3, and includes, for example, two sub-branch pipes 93 and 95. The feed pipe 91 connects the first branch pipe BK1 and the third branch pipe BK3. The sub-branch pipe 93 connects the third branch pipe BK3 and the nozzle 13C of the processing chamber 3C. Similarly, the sub-branch pipe 95 connects the third branch pipe BK3 and the nozzle 13D of the processing chamber 3D.

The second pump mechanism 43 further includes a filling pump FP2 and a discharge pump DP2. The filling pump FP2 is provided in the feed pipe 91 in the same layer as the housing casing 5, which is the layer lower than the processing chamber 3D, for example. The discharge pump DP2 is provided, for example, in the same layer as the processing chamber 3D, in the feed pipe 91 between the filling pump FP2 and the nozzle 13D of the processing chamber 3D. The discharge pump DP2 is provided on a side surface of the processing chamber 3D. The discharge pump DP2 is disposed at a position higher than the filling pump FP2.

The filling pump FP2 and the discharge pump DP2 of the second pump mechanism 43 are configured similarly to the filling pump FP and the discharge pump DP of the first pump mechanism 41, respectively.

The second pump mechanism 43 further includes a filter 81, an inlet valve IN, a first intermediate valve ISO, a second intermediate valve BAR, and two outlet valves OT3 and OT4. The filter 81 is provided in the feed pipe 91 between the filling pump FP2 and the discharge pump DP2. The inlet valve IN is provided in the feed pipe 91 at an upstream position of the filling pump FP2. The first intermediate valve ISO is provided in the feed pipe 91 between the filling pump FP2 and the filter 81. The second intermediate valve BAR is provided in the feed pipe 91 between the filter 81 and the discharge pump DP2.

The outlet valve OT3 is provided in the sub-branch pipe 93 between the discharge pump DP2 and the nozzle 13C of the processing chamber 3C. The outlet valve OT4 is provided in the sub-branch pipe 95 between the discharge pump DP2 and the nozzle 13D of the processing chamber 3D.

The second pump mechanism 43 further includes a return pipe 85, a second merging pipe GR2, and a purge valve PUR. In the second pump mechanism 43, the return pipe 85 connects the discharge pump DP2 and the second merging pipe GR2. The second merging pipe GR2 is provided in the feed pipe 91 between the first intermediate valve ISO and the inlet valve IN. The purge valve PUR is provided in the return pipe 85.

### 1-3. Configuration related to control

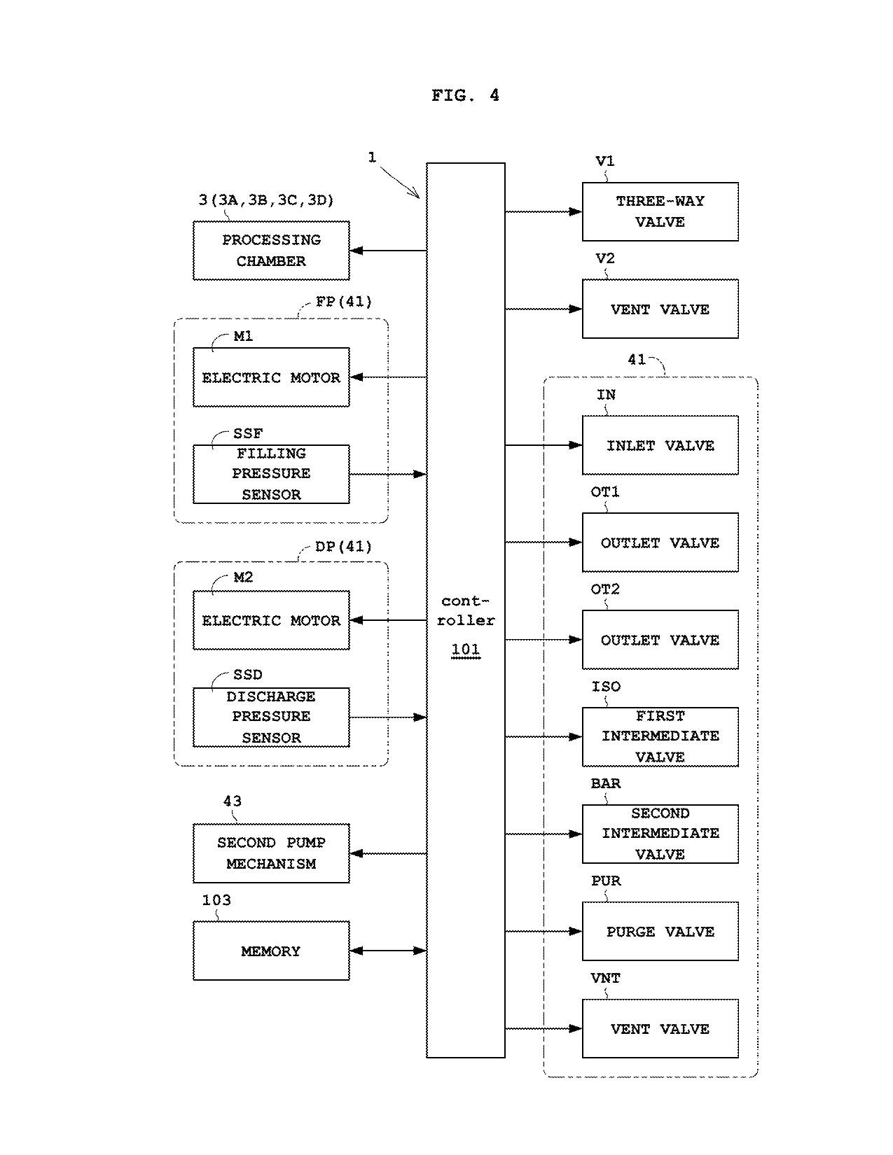

Reference is made to FIG. 4. The substrate processing apparatus 1 includes a controller 101 and a memory 103. The controller 101 controls each component of the substrate processing apparatus 1.

The controller 101 controls, for example, the four processing chambers 3A to 3D, the three-way valve V1, the vent valve V2, the first pump mechanism 41, and the second pump mechanism 43. The controller 101 controls the inlet valve IN, the first intermediate valve ISO, the second intermediate valve BAR, and the two outlet valves OT1 and OT2, the vent valve VNT, the purge valve PUR, and the two electric motors M1 and M2 in the first pump mechanism 41. The controller 101 receives a pressure value measured by each of the filling pressure sensor SSF and the discharge pressure sensor SSD.

The controller 101 includes one or more processors such as, for example, a central processing unit (CPU). The memory 103 is also referred to as a storage medium. The memory 103 includes, for example, at least one of a read-only memory (ROM), a random-access memory (RAM), and a hard disk. The memory 103 stores a computer program and a parameter necessary for controlling each component of the substrate processing apparatus 1. The controller 101 reads necessary information (for example, the parameter) from the memory 103.

The spin chuck 9 corresponds to a chuck of the present invention. Each of the processing chambers 3A to 3D corresponds to a first processing chamber of the present invention. When the processing chamber 3B is the first processing chamber, the nozzle 13B of the processing chamber 3B corresponds to a first nozzle of the present invention. The feed pipe 45 and the sub-branch pipe 48 correspond to a feed pipe of the present invention. The feed pipe of the present invention may include at least one of the sub-branch pipe 46 and the common pipe 21.

### 2. Operation of substrate processing apparatus

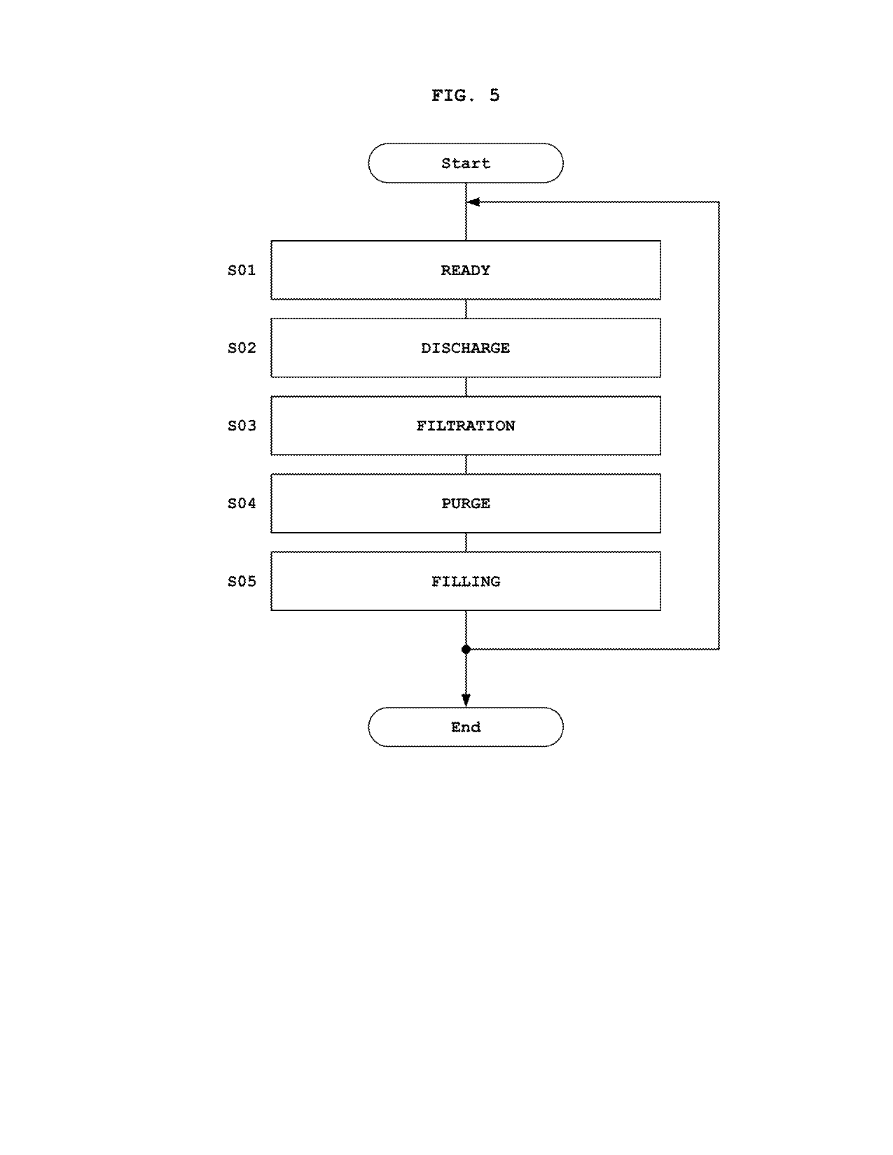

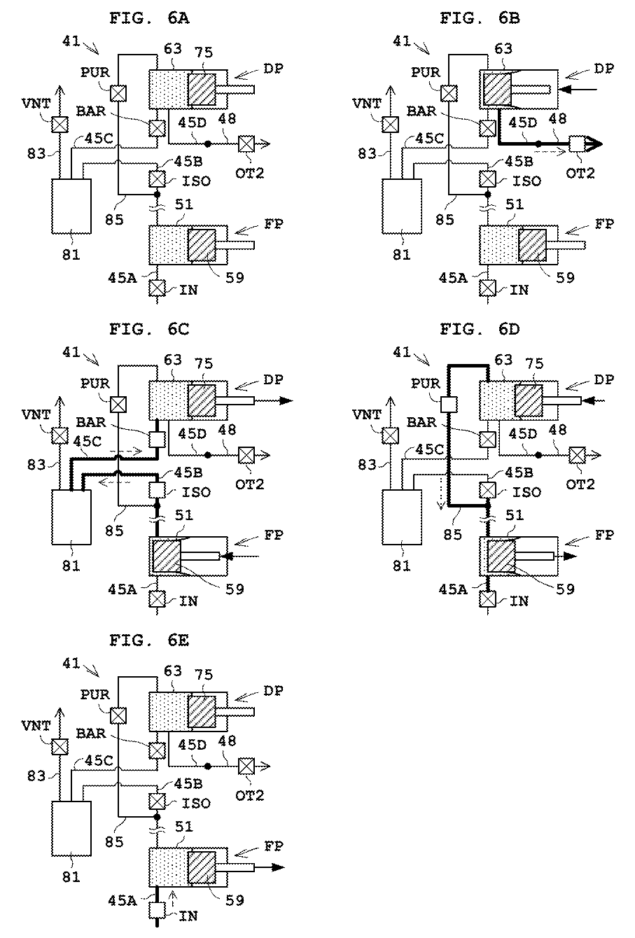

An operation of the substrate processing apparatus 1, particularly the liquid supply mechanism 7 will be described with reference to FIGS. 5 and 6A to 6E.

### 2-1. Outline of operation example of liquid supply mechanism 7

As the operation of the liquid supply mechanism 7, an operation example of sending the treatment liquid to the nozzle 13B of the processing chamber 3B will be described. This operation example is similarly performed when the treatment liquid is sent to each of the three nozzles 13A, 13C, and 13D of the other three processing chambers 3A, 3C, and 3D. In FIGS. 6A to 6E, the outlet valve OT1 (see FIG. 3) and the vent valve VNT are closed. In FIGS. 6A to 6E, each valve (for example, the inlet valve IN) is indicated by a square. Here, when X is attached to the square, the valve is in a closed state. On the other hand, when X is not attached to the square, the valve is in an open state.

### Step S01 Ready

FIG. 6A is a diagram showing a ready state. The ready state is formed by sequentially performing a discharge operation, a filtration operation, a purge operation, and a filling operation in steps S02 to S05. In FIG. 6A, the inlet valve IN, the outlet valve OT2, the first intermediate valve ISO, the second intermediate valve BAR, and the purge valve PUR are in a closed state.

### Step S02 Discharge

FIG. 6B is a diagram showing the discharge operation. Thereafter, the controller 101 opens the outlet valve OT2 in a state where the inlet valve IN, the outlet valve OT2, the first intermediate valve ISO, the second intermediate valve BAR, and the purge valve PUR are closed. In this state, the controller 101 causes the pump drive mechanism 73 to advance the second rod 75. In other words, the controller 101 causes the discharge pump DP to send the treatment liquid from the discharge pump DP toward the nozzle 13B while causing the discharge pump DP to adjust the pressure of the treatment liquid in the discharge pump DP so that the pressure value measured by the discharge pressure sensor SSD becomes a preset discharge pressure.

As a result, the nozzle 13B discharges the treatment liquid to the substrate W held by the spin chuck 9 of the processing chamber 3B.

### Step S03 Filtration

FIG. 6C is a diagram showing the filtration operation. Thereafter, the controller 101 causes the filling pump FP and the discharge pump DP to send the treatment liquid from the filling pump to the discharge pump so that the pressure value measured by the discharge pressure sensor SSD becomes a preset filtration pressure, in a state where the first intermediate valve ISO and the second intermediate valve BAR are opened and the inlet valve IN, the outlet valve OT2, and the purge valve PUR are closed. This operation is an actual filtration operation to be described later.

By the actual filtration operation, the treatment liquid sent from the filling pump FP is sent toward the discharge pump DP via the filter 81. Therefore, in the discharge pump DP, the treatment liquid in an amount necessary for performing the discharge operation and the purge operation in steps S02 and S04 is stored. The filter 81 captures air bubbles and particles in the treatment liquid. Details of the filtration operation will be described later.

### Step S04 Purge

FIG. 6D is a diagram showing the purge operation. Thereafter, the controller 101 slightly advances the second rod 75 of the discharge pump DP and slightly retreats the first rod 59 of the filling pump FP in a state where the purge valve PUR is opened and the inlet valve IN, the outlet valve OT2, the first intermediate valve ISO, and the second intermediate valve BAR are closed.

As a result, the air bubbles collected in the vicinity of the return outlet 69 in the discharge pump DP are returned toward the first merging pipe GR1 on an upstream side of the filter 81 through the return pipe 85. There is a possibility that particles are generated when the treatment liquid stagnates, but the generation of particles can be suppressed by causing the treatment liquid in the return pipe 85 to flow. Further, the air bubbles and the like in the treatment liquid in the discharge pump DP are returned to the first merging pipe GR1, and the returned air bubbles and the like are captured by the filter 81 in the next and subsequent filtration operations in step S03.

### Step S05Filling

FIG. 6E is a diagram showing the filling operation. Thereafter, the controller 101 retreats the first rod 59 of the filling pump FP so that the pressure value measured by the filling pressure sensor SSF becomes a preset filling pressure in a state where the inlet valve IN is opened and the outlet valve OT2, the first intermediate valve ISO, the second intermediate valve BAR, and the purge valve PUR are closed. At this time, for example, by connecting the two gas pipes 31 and 33 to the three-way valve V1, the positive pressure treatment liquid is sent from the treatment liquid bottle 23 into the filling pump FP through the trap tank 27. This brings the state into the ready state of FIG. 6A.

Note that steps S01 to S05 are repeatedly performed. When the treatment liquid is discharged from the nozzle 13A of the processing chamber 3A, the outlet valve OT1 is opened instead of the outlet valve OT2 in the discharge operation of step S02. The filling operation in step S05 may be performed in parallel with a part or all of the discharge operation in step S02.

### 2-2. Details of filtration operation in step S03

The filtration operation includes a pre-filtration operation and the actual filtration operation. The pre-filtration operation is a preparation operation for performing the actual filtration operation. In the pre-filtration operation, the first intermediate valve ISO and the second intermediate valve BAR are sequentially opened in order to prevent backflow.

The pre-filtration operation may have the following problems. For example, in the first pump mechanism 41, the discharge pump DP is disposed in a layer higher than the filling pump FP. Therefore, at the same time as opening the first intermediate valve ISO, the pressure value measured by the filling pressure sensor SSF may rapidly decrease. When the decrease in pressure per unit time is large, air bubbles may be generated inside the filling pump FP. Therefore, there is a demand for suppressing the rapid decrease in the pressure value.

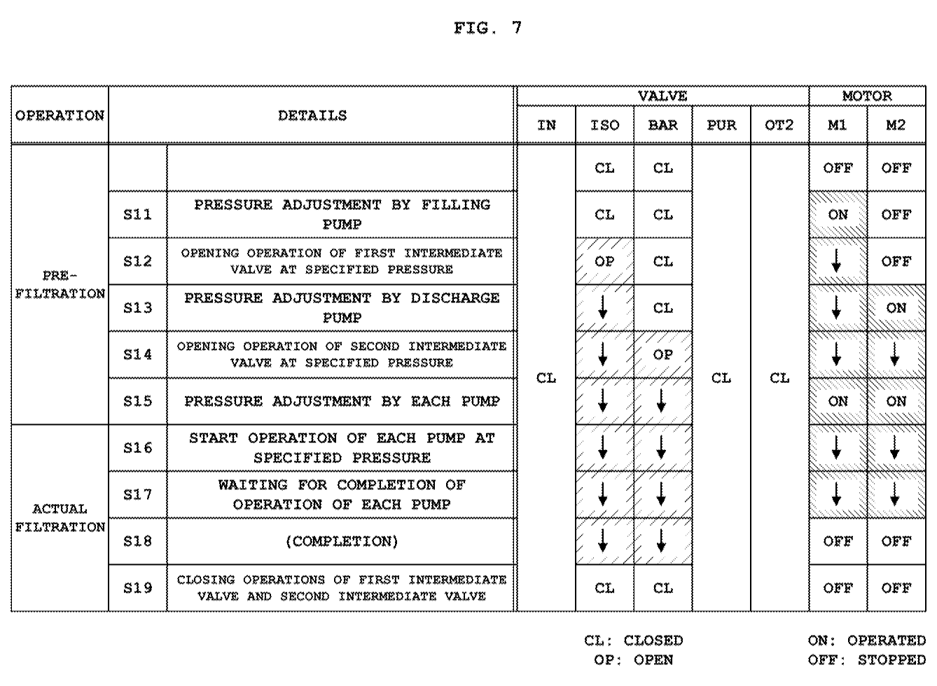

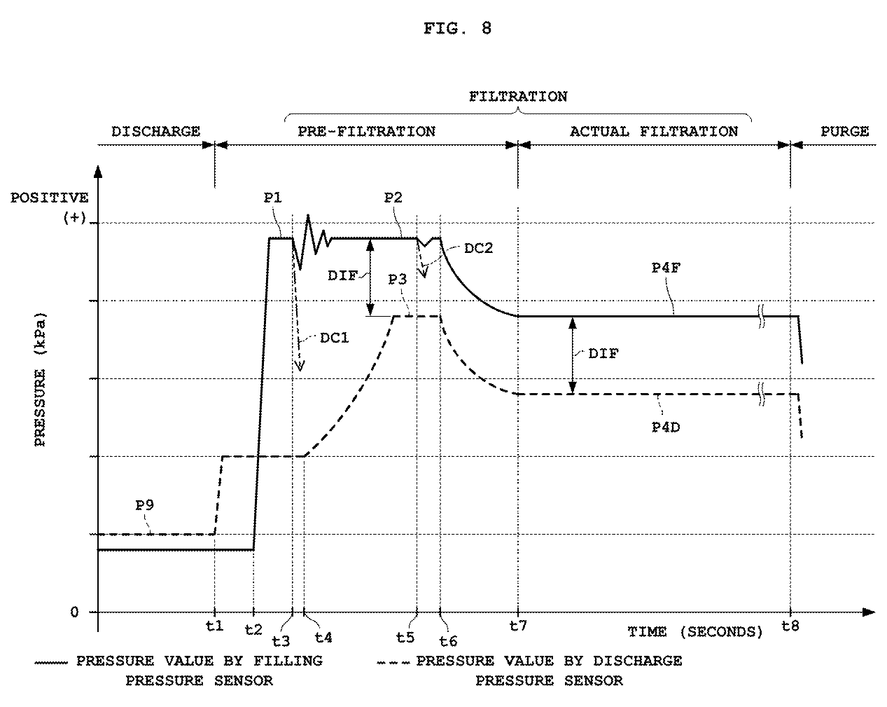

The controller 101 is configured to perform the pre-filtration operation and the actual filtration operation in this order. The pre-filtration operation and the actual filtration operation will be described in order with reference to FIGS. 7 and 8. FIG. 7 is a diagram for describing the filtration operation (the pre-filtration operation and the actual filtration operation). FIG. 8 is a diagram for describing a change in the pressure value measured by each of the filling pressure sensor and the discharge pressure sensor. In FIG. 8, a horizontal axis represents time, and a vertical axis represents a pressure value (kPa).

In the description of FIGS. 7 and 8, the vent valve VNT and the outlet valve OT1 remain closed (see FIG. 3). In FIG. 7, for example, when the first intermediate valve ISO is closed, reference sign CL is indicated. When the first intermediate valve ISO is open, reference sign OP is indicated. In addition, an arrow indicates that the operation of the previous step continues.

As shown in FIG. 7, steps S11 to S15 are the pre-filtration operation. Steps S16 to S18 are the actual filtration operation.

### Step S11 Pressure adjustment by filling pump

When the discharge operation in step S02 shown in FIG. 5 is completed, the inlet valve IN, the outlet valve OT2, the first intermediate valve ISO, the second intermediate valve BAR, and the purge valve PUR are in a closed state (time point t1 in FIG. 8). In this state, the controller 101 causes the filling pump FP to adjust the pressure of the treatment liquid in the filling pump FP so that the pressure value measured by the filling pressure sensor SSF becomes a first supply pressure P1 (time point t2 in FIG. 8).

At this time, the electric motor M1 of the filling pump FP adjusts the pressure by advancing and retreating the first rod 59 on the basis of the pressure value measured by the filling pressure sensor SSF.

In step S11, the electric motor M1 of the filling pump FP is operated (reference sign ON), and the electric motor M2 of the discharge pump DP is not operated (reference sign OFF). The electric motor M1 continues the operation in steps S11 to S14.

### Step S12 Opening operation of first intermediate valve at specified pressure

The controller 101 opens the first intermediate valve ISO when the pressure value measured by the filling pressure sensor SSF reaches the first supply pressure P1 (time point t3 in FIG. 8). As a result, the treatment liquid is pushed to the second intermediate valve BAR. At the time of opening the first intermediate valve ISO, the inlet valve IN, the outlet valve OT2, the second intermediate valve BAR, and the purge valve PUR are in a closed state.

Here, as indicated by a two-dot chain line of reference sign DC1 in FIG. 8, when the first intermediate valve ISO is opened, the pressure of the treatment liquid in the filling pump FP may be greatly reduced. Therefore, the filling pump FP adjusts the pressure of the treatment liquid continuously from steps S11 and S12. In step S12, the electric motor M1 of the filling pump FP continues the operation. That is, the filling pump FP is adjusting the pressure of the treatment liquid.

A specific operation will be described. During a period from the opening of the first intermediate valve ISO to the opening of the second intermediate valve BAR, the controller 101 causes the filling pump FP to adjust the pressure of the treatment liquid in the filling pump FP so that the pressure value measured by the filling pressure sensor SSF becomes a second supply pressure P2 in a state where the first intermediate valve ISO is opened and the inlet valve IN, the outlet valve OT2, the second intermediate valve BAR, and the purge valve PUR are closed. The second supply pressure P2 is the same as the first supply pressure P1, but may be different from the first supply pressure P1.

### Step S13 Pressure adjustment by discharge pump

Here, as indicated by a two-dot chain line of reference sign DC2 in FIG. 8, when the second intermediate valve BAR is opened, the pressure of the treatment liquid in the filling pump FP may be reduced. Therefore, the discharge pump DP adjusts the pressure of the treatment liquid on an outflow side (secondary side) of the second intermediate valve BAR so that the pressures of the treatment liquid on an inflow side (primary side) and the outflow side (secondary side) of the second intermediate valve BAR become substantially the same.

A specific operation will be described. The controller 101 keeps the first intermediate valve ISO in an open state and keeps the inlet valve IN, the outlet valve OT2, the second intermediate valve BAR, and the purge valve PUR in a closed state, after the first intermediate valve ISO is opened and before the second intermediate valve BAR is opened. In this state, the controller 101 causes the discharge pump DP to adjust the pressure of the treatment liquid in the discharge pump DP so that the pressure value measured by the discharge pressure sensor SSD becomes a predetermined third supply pressure P3 on the inflow side of the second intermediate valve BAR (time point t4 in FIG. 8).

The “inflow side of the second intermediate valve BAR” is, for example, a position indicated by reference sign ST1 in FIG. 3. The position is adjacent to the second intermediate valve BAR. The third supply pressure P3 is adjusted so that the pressures of the treatment liquid on the inflow side and the outflow side of the second intermediate valve BAR are substantially the same. The pressure on the inflow side of the second intermediate valve BAR can be measured in advance by experiment. In addition, it is also possible to set a predetermined pressure by adding a correction value (for example, a pressure difference due to a height difference between the filling pump FP and the discharge pump DP) to the second supply pressure P2.

In step S13, the electric motor M1 of the filling pump FP continues the operation. That is, the filling pump FP is adjusting the pressure of the treatment liquid on the inflow side (primary side) of the second intermediate valve BAR. In step S13, the electric motor M2 of the discharge pump DP adjusts the pressure by advancing and retreating the second rod 75 on the basis of the pressure value measured by the discharge pressure sensor SSD. The electric motor M2 continues the operation (pressure adjustment) in steps S13 to S14.

### Step S14 Opening operation of second intermediate valve at specified pressure

When the pressure value measured by the discharge pressure sensor SSD reaches the third supply pressure P3, the controller 101 opens the second intermediate valve BAR (time point t5 in FIG. 8). At the time of opening the second intermediate valve BAR, the first intermediate valve ISO is in an open state, and the inlet valve IN, the outlet valve OT2, and the purge valve PUR are in a closed state.

As described above, the pressure adjustment by the discharge pump DP is performed so that the pressures of the treatment liquid on the inflow side and the outflow side of the second intermediate valve BAR become substantially the same. Therefore, it is possible to suppress a decrease in the pressure of the treatment liquid in the filling pump FP when the second intermediate valve BAR is opened.

### Step S15 Pressure adjustment by each pump

In step S15, the first intermediate valve ISO and the second intermediate valve BAR are in an opened state, and the inlet valve IN, the outlet valve OT2, and the purge valve PUR are in a closed state. At this time, as shown in FIG. 8, due to a height difference between the filling pump FP and the discharge pump DP, two pressure values measured by the filling pressure sensor SSF and the discharge pressure sensor SSD have a pressure difference (see reference sign DIF in FIG. 8).

The filling pump FP and the discharge pump DP (at least the filling pump FP) adjust the pressure so that the pressure value measured by the discharge pressure sensor SSD becomes a filtration pressure P4D. When the treatment liquid in the discharge pump DP has the filtration pressure P4D, the treatment liquid in the filling pump FP has a filtration pressure P4F by the pressure difference (reference sign DIF). The filtration pressure P4F is larger than the filtration pressure P4D (filtration pressure P4F > filtration pressure P4D).

A specific operation will be described. After opening the second intermediate valve BAR, the controller 101 keeps the first intermediate valve ISO and the second intermediate valve BAR in an open state and keeps the inlet valve IN, the outlet valve OT2, and the purge valve PUR in a closed state. In this state, the controller 101 causes the filling pump FP and the discharge pump DP to adjust the pressure in the discharge pump DP so that the pressure value measured by the discharge pressure sensor SSD becomes the filtration pressure P4D (between time points t6 and t7 in FIG. 8). The pressure adjustment in step S15 is performed over, for example, about 1 to 1.5 seconds so that the pressure value does not rapidly decrease.

### Steps S16 to S19 Actual filtration operation

When the pressure value measured by the discharge pressure sensor SSD reaches the filtration pressure P4D, the controller 101 keeps the first intermediate valve ISO and the second intermediate valve BAR in an open state, and keeps the inlet valve IN, the outlet valve OT2, and the purge valve PUR in a closed state. In this state, the controller 101 causes the filling pump FP and the discharge pump DP to send the treatment liquid from the filling pump FP toward the discharge pump DP (between time points t7 and t8 in FIG. 8) so that the pressure value measured by the discharge pressure sensor SSD maintains the filtration pressure P4D (at the filtration pressure).

That is, when the pressure value measured by the discharge pressure sensor SSD reaches the filtration pressure P4D, the pump operations of the filling pump FP and the discharge pump DP are started (step S16). The electric motor M1 of the filling pump FP mainly advances the first rod 59, and the electric motor M2 of the discharge pump DP mainly retreats the second rod 75. As a result, while maintaining the filtration pressure P4D, the filling pump FP sends out the treatment liquid, and the discharge pump DP receives the treatment liquid.

Completion of the pump operations of the filling pump FP and the discharge pump DP is awaited (step S17). When the pump operations are completed, the operation of each of the electric motors M1 and M2 is stopped (step S18, see FIG. 6C). Thereafter, the first intermediate valve ISO and the second intermediate valve BAR are closed together (step S19, time point t8 in FIG. 8). Thereafter, the purge operation in step S04 shown in FIG. 5 is performed.

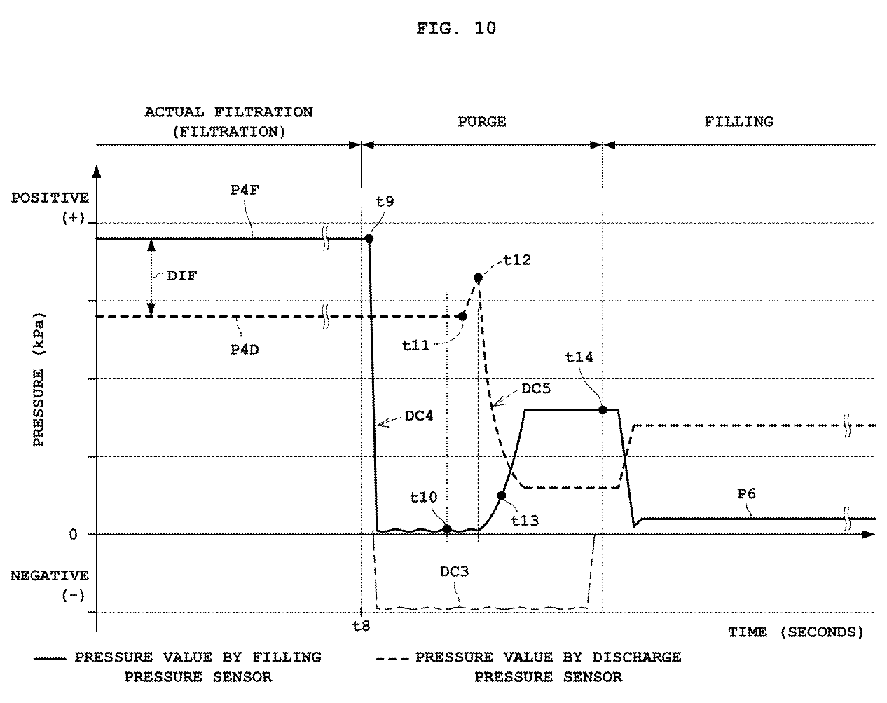

As shown in FIG. 8, the first supply pressure P1, the second supply pressure P2, the third supply pressure P3, and the filtration pressures P4D and P4F are positive values. The first supply pressure P1 and the second supply pressure P2 are larger than the filtration pressure P4F. The filtration pressure P4F is larger than a filling pressure P6 (see FIG. 10).

According to the substrate processing apparatus 1 of the present embodiment, the pre-filtration operation that is a preparation operation of the actual filtration operation is performed before the actual filtration operation. In the pre-filtration operation, when each of the first intermediate valve ISO and the second intermediate valve BAR is opened, the pressure of the treatment liquid in the filling pump FP may be greatly reduced. According to the present embodiment, during a period from the opening of the first intermediate valve ISO to the opening of the second intermediate valve BAR, the filling pump FP adjusts the pressure of the treatment liquid in the filling pump FP so that the pressure value measured by the filling pressure sensor SSF becomes the second supply pressure P2, in a state where the first intermediate valve ISO is opened and the inlet valve IN, the outlet valve OT2, and the second intermediate valve BAR are closed. Therefore, even when the first intermediate valve ISO is opened, it is possible to suppress a large decrease in the pressure of the treatment liquid in the filling pump FP.

According to the present embodiment, during a period from the opening of the first intermediate valve ISO to the opening of the second intermediate valve BAR, the discharge pump DP adjusts the pressure of the treatment liquid in the discharge pump DP so that the pressure value measured by the discharge pressure sensor SSD becomes the third supply pressure P3 on the inflow side of the second intermediate valve BAR, in a state where the first intermediate valve ISO is opened and the inlet valve IN, the second intermediate valve BAR, and the outlet valve OT2 are closed. As a result, the pressures of the treatment liquid on the inflow side and the outflow side of the second intermediate valve BAR become substantially the same. Even when the second intermediate valve BAR is opened, a decrease in the pressure of the treatment liquid in the filling pump FP is suppressed. As a result, generation of air bubbles in the treatment liquid can be suppressed.

### Second embodiment

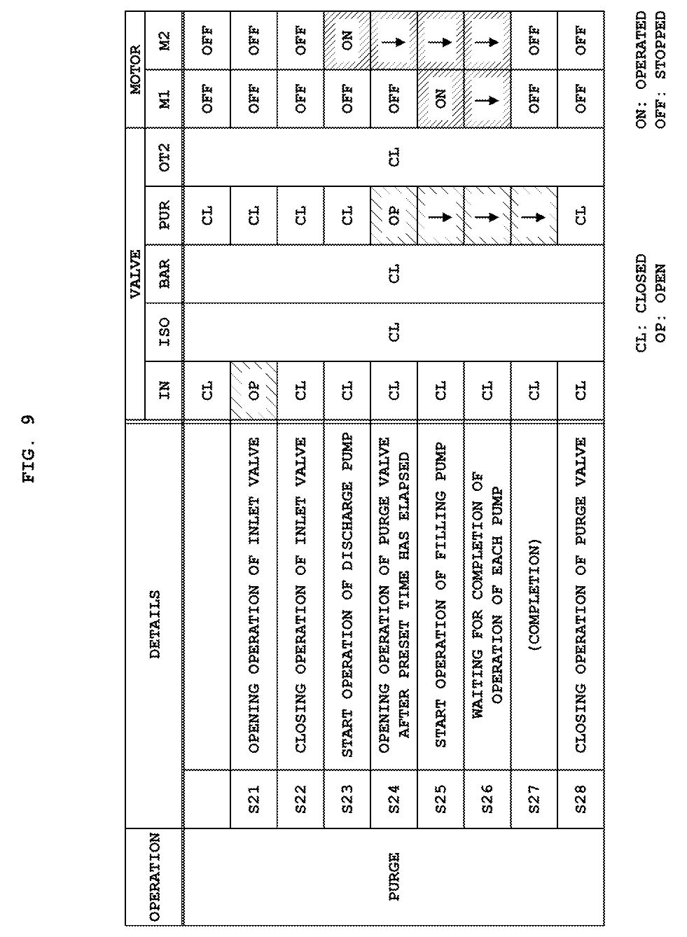

Next, a second embodiment of the present invention will be described with reference to the drawings. Note that description common to the first embodiment will be omitted. FIG. 9 is a diagram for describing a purge operation according to the second embodiment. FIG. 10 is a diagram for describing a change in a pressure value measured by each of a filling pressure sensor and a discharge pressure sensor according to the second embodiment. In the first embodiment, generation of air bubbles in the pre-filtration operation is suppressed. In this regard, in the second embodiment, generation of air bubbles in the purge operation is suppressed.

### 3. Details of purge operation in step S04

Conventionally, the purge operation is performed by opening an inlet valve IN and a purge valve PUR to be released to the atmosphere. As a result, pressures of treatment liquids in a filling pump FP and a discharge pump DP are reduced to substantially 0 (zero) kPa.

The purge operation may have the following problems. As shown in FIG. 2, for example, in a first pump mechanism 41, the discharge pump DP is disposed in a layer higher than the filling pump FP. It is assumed that both the inlet valve IN and the purge valve PUR are opened in a state where an outlet valve OT2, a first intermediate valve ISO, and a second intermediate valve BAR are closed. In this case, the pressure of the treatment liquid in the filling pump FP drops to almost 0 (zero) kPa. On the other hand, an inside of the discharge pump DP has a negative pressure as indicated by reference sign DC3 in FIG. 10. When the pressure becomes the negative pressure, air bubbles are likely to be generated in the treatment liquid in the discharge pump DP, and as this negative pressure state is continued, more air bubbles are generated.

When each of the inlet valve IN and the purge valve PUR is opened as indicated by reference sign DC4 in FIG. 10, for example, the pressure is relatively rapidly reduced. Therefore, air bubbles may be generated in the treatment liquid for a moment. As compared with the generation of air bubbles at this time, more air bubbles are generated when the negative pressure state is continued.

Therefore, in the second embodiment, generation of air bubbles in the purge operation is suppressed. The purge operation of the second embodiment will be described with reference to FIGS. 9 and 10. Also in the second embodiment, an outlet valve OT1 and a vent valve VNT are closed. At time point t8 in FIG. 10, the inlet valve IN, the outlet valve OT2, the first intermediate valve ISO, the second intermediate valve BAR, and the purge valve PUR are in a closed state.

### Step S21 Opening operation of inlet valve

A controller 101 opens the inlet valve IN in a state where the outlet valve OT2, the first intermediate valve ISO, the second intermediate valve BAR, and the purge valve PUR are closed (time point t9 in FIG. 10). A three-way valve V1 connects a gas pipe 31 and a vent pipe 35, and gas in a treatment liquid bottle 23 is at atmospheric pressure. As a result, the treatment liquid in the filling pump FP is released to an upstream side of atmospheric pressure of the inlet valve IN. In addition, the treatment liquid in a return pipe 85 and a feed pipe 45 (pipes 45A and 45B) from the purge valve PUR to the inlet valve IN is released to the upstream side of atmospheric pressure of the inlet valve IN.

### Step S22 Closing operation of inlet valve

The controller 101 closes the inlet valve IN after a preset time (for example, 0.5 seconds) has elapsed since the opening of the inlet valve IN so that the pressure value measured by the discharge pressure sensor SSD does not become a negative pressure when the purge valve PUR is opened (time point t10 in FIG. 10). The pressure in the filling pump FP drops to almost 0 (zero) kPa.

### Step S23 Start operation of discharge pump

After closing the inlet valve IN and before opening the purge valve PUR, the controller 101 causes the discharge pump DP to start pushing the treatment liquid from the discharge pump DP toward the purge valve PUR through the return pipe 85 in a state where the inlet valve IN, the outlet valve OT2, the first intermediate valve ISO, the second intermediate valve BAR, and the purge valve PUR are closed (time point t11 in FIG. 10). Thus, the pressure of the treatment liquid in the discharge pump DP increases.

In step S23, an electric motor M2 of the discharge pump DP advances a second rod 75. The advancing is performed at a preset speed (for example, a constant speed). An operation of the electric motor M2 is continued in steps S23 to S26.

### Step S24 Opening operation of purge valve after preset time has elapsed

The controller 101 opens the purge valve PUR in a state where the inlet valve IN, the outlet valve OT2, the first intermediate valve ISO, and the second intermediate valve BAR are closed, after a preset time (for example, 50 milliseconds) has elapsed since the start of the pushing of the treatment liquid through the return pipe 85 (time point t12 in FIG. 10). That is, the purge valve PUR is opened later than the start of the pushing of the treatment liquid by the discharge pump DP.

When the purge valve PUR is opened, the inlet valve IN is closed. Therefore, the treatment liquid in the discharge pump DP is not excessively pulled toward the filling pump FP through the return pipe 85. Therefore, the treatment liquid in the discharge pump DP can be prevented from having a negative pressure. Before the purge valve PUR is opened, the treatment liquid starts to be pushed toward the purge valve PUR. That is, the pressure of the treatment liquid in the discharge pump DP is increased. Therefore, it is possible to further suppress the treatment liquid in the discharge pump DP from having a negative pressure when the purge valve PUR is opened. In addition, the pressure in the discharge pump DP can be relatively gently reduced.

When the purge valve PUR is opened, the treatment liquid in the discharge pump DP is pulled toward the filling pump FP. The discharge pump DP is in a layer higher than the filling pump FP. As a result, the pressure of the treatment liquid in the discharge pump DP decreases and the pressure of the treatment liquid in the filling pump FP increases (see FIG. 10).

### Step S25 Start operation of filling pump (actual purge operation)

After opening the purge valve PUR, the controller 101 causes the filling pump FP to suck (receive) the treatment liquid sent through the return pipe 85 and a first merging pipe GR1 in a state where the purge valve PUR is opened and the inlet valve IN, the outlet valve OT2, the first intermediate valve ISO, and the second intermediate valve BAR are closed (time point t13 in FIG. 10).

The filling pump FP sucks the treatment liquid so that the pressure value measured by the filling pressure sensor SSF becomes a positive value. The filling pump FP sucks the same amount of the treatment liquid as the treatment liquid sent out from the discharge pump DP toward the purge valve PUR through the return pipe 85. For example, when the discharge pump DP advances the second rod 75 by a second distance, the filling pump FP retreats a first rod 59 by a first distance having the same length as the second distance. Note that the second distance is a movement distance from time point t11, and the first distance is a movement distance from time point t13. The first distance and the second distance are preset.

In step S25, the controller 101 causes the discharge pump DP to continue pushing the treatment liquid from the discharge pump DP toward the purge valve PUR through the return pipe 85. That is, in step S25, after opening the purge valve PUR, the controller 101 performs an actual purge operation of causing the filling pump FP and the discharge pump DP to return the treatment liquid from the discharge pump DP toward the filling pump through the return pipe 85 in a state where the purge valve PUR is opened and the inlet valve IN, the outlet valve OT2, the first intermediate valve ISO, and the second intermediate valve BAR are closed.

The electric motor M1 of the filling pump FP retreats the first rod 59. The retreating is performed at a preset speed (for example, a constant speed). The electric motor M1 continues the operation in steps S25 to S26.

### Steps S26 to S28 Waiting for completion of operation of each pump to closing operation of purge valve

In the actual purge operation, completion of the pump operations of the filling pump FP and the discharge pump DP is awaited (step S26). When the pump operations are completed, the operation of each of the electric motors M1 and M2 is stopped (step S27).

Thereafter, the purge valve PUR is closed (step S28, time point t14 in FIG. 10). Thereafter, the filling operation in step S05 shown in FIG. 5 is performed. In the filling operation, when the pressure of the treatment liquid in the filling pump FP is high, the inlet valve IN may be opened in a state where the outlet valve OT2, the first intermediate valve ISO, the second intermediate valve BAR, and the purge valve PUR are closed. As a result, the pressure value measured by the filling pressure sensor SSF becomes substantially 0 (zero). The pressure value measured by the discharge pressure sensor SSD from time points t8 to t14 is preferably a positive value.

According to the present embodiment, the purge operation is performed. In the purge operation, when the inlet valve IN and the purge valve PUR are opened, the treatment liquid in the discharge pump DP is pulled toward the filling pump FP due to a height difference between the filling pump FP and the discharge pump DP, and as a result, the pressure of the treatment liquid in the discharge pump DP may become a negative pressure. According to the present embodiment, the inlet valve IN is closed after a preset time has elapsed since the opening of the inlet valve IN so that the pressure value measured by the discharge pressure sensor SSD does not become a negative pressure when the purge valve PUR is opened. Therefore, even when the purge valve PUR is opened, it is possible to suppress the pressure of the treatment liquid in the discharge pump DP from becoming a negative pressure, and as a result, generation of air bubbles in the treatment liquid can be suppressed.

Before the purge valve PUR is opened, the treatment liquid starts to be pushed toward the purge valve PUR. That is, the pressure of the treatment liquid in the discharge pump DP is increased. Therefore, it is possible to further suppress the treatment liquid in the discharge pump DP from having a negative pressure when the purge valve PUR is opened. In addition, the pressure in the discharge pump DP can be relatively gently reduced (see reference sign DC5 in FIG. 10). When the pressure is relatively gently reduced, generation of air bubbles in the treatment liquid can be suppressed.

### Third embodiment

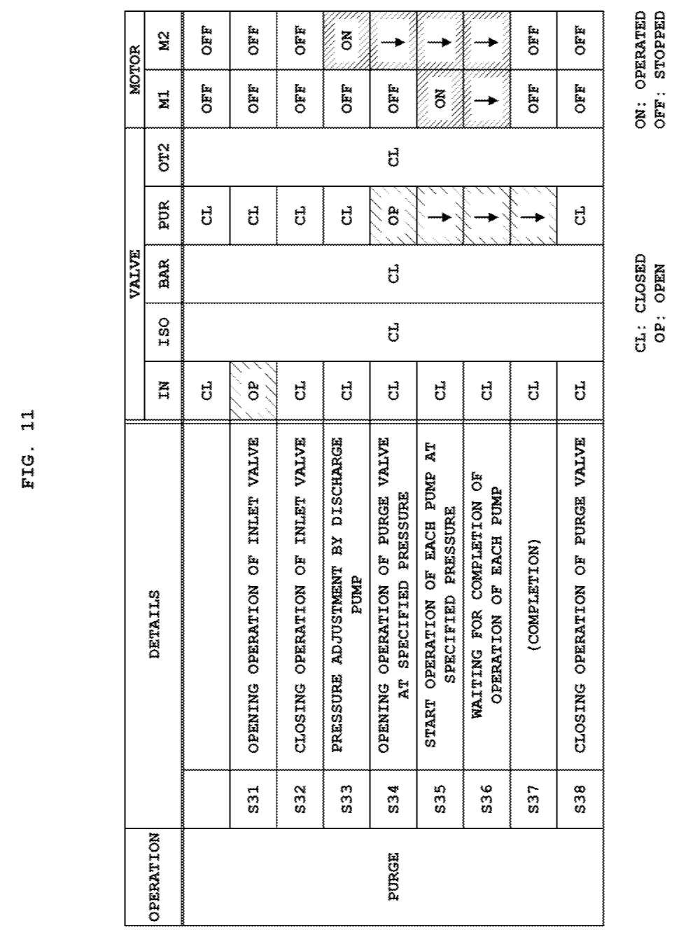

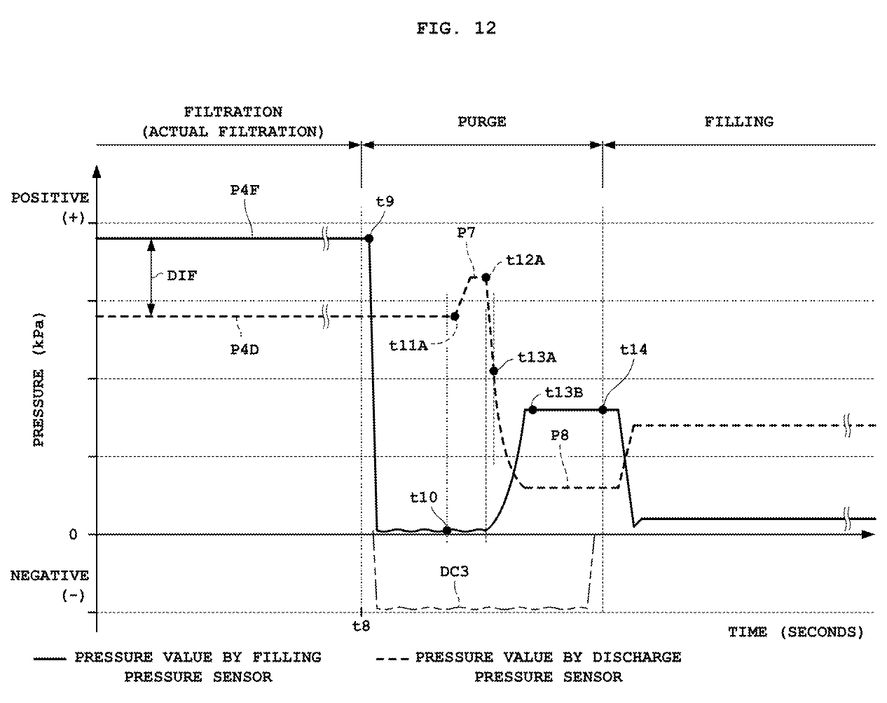

Next, a third embodiment of the present invention will be described with reference to the drawings. Note that description common to the first and second embodiments will be omitted. FIG. 11 is a diagram for describing a purge operation according to the third embodiment. FIG. 12 is a diagram for describing a change in a pressure value measured by each of a filling pressure sensor and a discharge pressure sensor according to the third embodiment.

The third embodiment relates to a purge operation. In the second embodiment, the purge valve PUR is opened after the discharge pump DP starts pushing the treatment liquid toward the purge valve PUR. In this regard, in the third embodiment, a purge valve PUR may be opened when the pressure value measured by the discharge pressure sensor SSD reaches a preset first purge pressure P7.

### 4. Details of another purge operation in step S04

The purge operation of the third embodiment will be described with reference to FIGS. 11 and 12. Also in the third embodiment, an outlet valve OT1 and a vent valve VNT are closed. Common description is omitted.

An inlet valve IN is opened (step S31, time point t9 in FIG. 12). As a result, a treatment liquid in a filling pump FP is released to an upstream side of atmospheric pressure of the inlet valve IN (for example, a treatment liquid bottle 23 side). In addition, the treatment liquid in a return pipe 85 and a feed pipe 45 (pipes 45A and 45B) from the purge valve PUR to the inlet valve IN is released to the upstream side of atmospheric pressure of the inlet valve IN. Thereafter, the inlet valve IN is closed after a preset time has elapsed since the opening of the inlet valve IN (step S32, time point t10 in FIG. 12).

### Step S33 Pressure adjustment by discharge pump

After closing the inlet valve IN and before opening the purge valve PUR, a controller 101 causes a discharge pump DP to adjust a pressure of the treatment liquid in the discharge pump DP so that the pressure value measured by the discharge pressure sensor SSD becomes the first purge pressure P7 in a state where the inlet valve IN, an outlet valve OT2, a first intermediate valve ISO, a second intermediate valve BAR, and the purge valve PUR are closed (time point t11A in FIG. 12). As a result, the pressure of the treatment liquid in the discharge pump DP increases.

In step S33, an electric motor M2 of the discharge pump DP mainly advances a second rod 75. The electric motor M2 may retreat the second rod 75. An operation of the electric motor M2 is continued in steps S33 to S36.

### Step S34Opening operation of purge valve at specified pressure

When the pressure value measured by the discharge pressure sensor SSD reaches the first purge pressure P7, the controller 101 opens the purge valve PUR in a state where the inlet valve IN, the outlet valve OT2, the first intermediate valve ISO, and the second intermediate valve BAR are closed (time point t12A in FIG. 12).

After opening the purge valve PUR, the controller 101 causes the discharge pump DP to adjust the pressure of the treatment liquid in the discharge pump DP so that the pressure value measured by the discharge pressure sensor SSD becomes a second purge pressure P8 in a state where the purge valve PUR is opened and the inlet valve IN, the outlet valve OT2, the first intermediate valve ISO, and the second intermediate valve BAR are closed. That is, the pressure adjustment of the treatment liquid in the discharge pump DP is started (time point t13A in FIG. 12).

### Step S35 Start operation of each pump at specified pressure (actual purge operation)

Then, when the pressure value measured by the discharge pressure sensor SSD reaches the second purge pressure P8, the controller 101 causes the filling pump FP and the discharge pump DP to return the treatment liquid from the discharge pump DP toward the filling pump FP through the return pipe 85 so that the pressure value measured by the discharge pressure sensor SSD maintains the second purge pressure P8 (between time points t13B and t14 in FIG. 12). In other words, the controller 101 performs an actual purge operation. During this operation, the controller 101 keeps the purge valve PUR in an open state and keeps the inlet valve IN, the outlet valve OT2, the first intermediate valve ISO, and the second intermediate valve BAR in a closed state.

In the actual purge operation, a first rod 59 and the second rod 75 are moved by substantially the same amount. An electric motor M1 of the filling pump FP mainly retreats the first rod 59. The electric motor M1 may advance the first rod 59. The electric motor M1 continues the operation in steps S35 to S36.

The first purge pressure P7 and the second purge pressure P8 are both positive values. The first purge pressure P7 is preferably larger than the filtration pressure P4D. The first purge pressure P7 is preferably larger than the second purge pressure P8. The second purge pressure P8 is preferably smaller than the filtration pressure P4D and a discharge pressure P9 (see FIG. 8).

### Steps S36 to S38 Waiting for completion of operation of each pump to closing operation of purge valve

In the actual purge operation, completion of the pump operation of the filling pump FP and the discharge pump DP is awaited (step S36). When the pump operations are completed, the operation of each of the electric motors M1 and M2 is stopped (step S37). Thereafter, the purge valve PUR is closed (step S28, time point t14 in FIG. 12).

According to the present embodiment, the inlet valve IN is closed after a preset time has elapsed since the opening of the inlet valve IN so that the pressure value measured by the discharge pressure sensor SSD does not become a negative pressure when the purge valve PUR is opened. Therefore, even when the purge valve PUR is opened, it is possible to suppress the pressure of the treatment liquid in the discharge pump DP from becoming a negative pressure, and as a result, generation of air bubbles in the treatment liquid can be suppressed.

Before the purge valve PUR is opened, the discharge pump DP adjusts the pressure of the treatment liquid in the discharge pump DP so that the pressure value measured by the discharge pressure sensor SSD becomes the first purge pressure P7. After the purge valve PUR is opened, the discharge pump DP adjusts the pressure of the treatment liquid in the discharge pump DP so that the pressure value measured by the discharge pressure sensor SSD becomes the second purge pressure P8. That is, the pressure of the treatment liquid is adjusted before and after the opening operation of the purge valve PUR. Therefore, it is possible to further suppress the treatment liquid in the discharge pump DP from having a negative pressure when the purge valve PUR is opened. In addition, the pressure in the discharge pump DP can be relatively gently reduced.

The present invention is not limited to the above described embodiments, and can be modified as follows.
(1) In the above-described embodiments, the first pump mechanism 41 supplies the treatment liquid to the two processing chambers 3A and 3B. In this regard, the first pump mechanism 41 may supply the treatment liquid to one or three or more processing chambers.
(2) In the above-described embodiments and modification (1), the housing casing 5 is provided in the lower layer of the four processing chambers 3A to 3D. In this regard, the housing casing 5 may not be provided. In this case, for example, the treatment liquid bottle 23, the trap tank 27, and the filling pump FP of the first pump mechanism 41 may be disposed in the same layer as at least one of the processing chambers 3C and 3D.
(3) In the above-described embodiments and modifications, the distal end of the return pipe 85 is connected to the first merging pipe GR1 of the pipe 45B. In this regard, the distal end of the return pipe 85 may be connected to the filling pump FP. As a result, the treatment liquid sent by the return pipe 85 can be directly returned into the filling pump FP. However, since the filling pump FP is provided in the same layer as the housing casing 5, the return pipe 85 becomes long. As a result, particles may be likely to be generated.
(4) In the above-described embodiments and modifications, the substrate processing apparatus 1 includes the single tower having the plurality of processing chambers 3 and the housing casing 5 stacked in the vertical direction Z. In this regard, the substrate processing apparatus 1 may include a plurality of towers. Each tower includes the plurality of processing chambers 3 and the housing casing 5 stacked in the vertical direction Z.
(5) In the above-described embodiments and modifications, for example, the discharge pump DP of the first pump mechanism 41 is provided outside the processing chamber 3B. In this regard, the discharge pump DP may be provided inside the processing chamber 3B.
(6) In the above-described embodiments and modifications, the vent pipe 39 provided with the vent valve V2 is connected to the trap tank 27. The inside of the trap tank 27 may be brought to atmospheric pressure by opening the vent valve V2.
(7) In the above-described embodiments and modifications, the first intermediate valve ISO, the second intermediate valve BAR, and the filter 81 are each disposed, for example, in the same layer as the processing chamber 3B or in the layer higher than the processing chamber 3B. In this regard, at least one of the first intermediate valve ISO, the second intermediate valve BAR, and the filter 81 may be provided in the same layer as the filling pump FP (for example, the same layer as the housing casing 5).

For example, it is assumed that the first intermediate valve ISO is provided in the same layer as the filling pump FP, and the second intermediate valve BAR is provided in the same layer as the processing chamber 3B. In this case, when the second intermediate valve BAR is opened, the pressure of the treatment liquid in the filling pump FP may be greatly reduced.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus configured to processes a substrate, comprising:
a plurality of processing chambers stacked in a vertical direction;
a liquid supply mechanism configured to supply a treatment liquid to at least one of the plurality of processing chambers; and
a controller, wherein
each of the plurality of processing chambers includes
a chuck configured to hold a substrate, and
a nozzle configured to discharge the treatment liquid to the substrate held by the chuck,
the liquid supply mechanism includes
a feed pipe configured to supply the treatment liquid to a first nozzle that is the nozzle of a first processing chamber among the plurality of processing chambers,
a filling pump provided in the feed pipe in a layer lower than the first processing chamber,
a discharge pump provided in the feed pipe between the filling pump and the first nozzle in a layer same as the first processing chamber or in a layer higher than the first processing chamber,
an inlet valve provided in the feed pipe at an upstream position of the filling pump,
an outlet valve provided in the feed pipe between the discharge pump and the first nozzle,
a filter provided in the feed pipe between the filling pump and the discharge pump,
a first intermediate valve provided in the feed pipe between the filling pump and the filter, and
a second intermediate valve provided in the feed pipe between the filter and the discharge pump,
the filling pump includes a filling pressure sensor configured to measure a pressure of the treatment liquid in the filling pump,
the discharge pump includes a discharge pressure sensor configured to measure a pressure of the treatment liquid in the discharge pump,
the controller is configured to perform a pre-filtration operation and an actual filtration operation in this order, and
as the pre-filtration operation, the controller is configured to
cause the filling pump to adjust the pressure of the treatment liquid in the filling pump so that a pressure value measured by the filling pressure sensor becomes a first supply pressure in a state where the inlet valve, the outlet valve, the first intermediate valve, and the second intermediate valve are closed,
push the treatment liquid to the second intermediate valve by opening the first intermediate valve when the pressure value measured by the filling pressure sensor reaches the first supply pressure,
during a period from the opening of the first intermediate valve to opening of the second intermediate valve, cause the filling pump to adjust the pressure of the treatment liquid in the filling pump so that the pressure value measured by the filling pressure sensor becomes a second supply pressure in a state where the inlet valve and the second intermediate valve are closed,
after the first intermediate valve is opened, cause the discharge pump to adjust the pressure of the treatment liquid in the discharge pump so that a pressure value measured by the discharge pressure sensor becomes a third supply pressure in a state where the outlet valve and the second intermediate valve are closed, and
open the second intermediate valve when the pressure value measured by the discharge pressure sensor reaches the third supply pressure, and
as the actual filtration operation, the controller is configured to
cause the treatment liquid to be sent from the filling pump toward the discharge pump in a state where the inlet valve and the outlet valve are closed.

2. The substrate processing apparatus according to claim 1, wherein
the liquid supply mechanism further includes
a return pipe configured to connect the discharge pump and a return position in the feed pipe between the first intermediate valve and the inlet valve, and
a purge valve provided in the return pipe, and
as a purge operation, the controller is configured to
open the inlet valve in a state where the first intermediate valve and the purge valve are closed to release the treatment liquid in the filling pump to an upstream side of atmospheric pressure of the inlet valve,
close the inlet valve after a preset time has elapsed since the opening of the inlet valve so that the pressure value measured by the discharge pressure sensor does not become a negative pressure when the purge valve is opened,
after closing the inlet valve, perform a purge valve opening operation to open the purge valve in a state where the outlet valve, the first intermediate valve, and the second intermediate valve are closed, and
after opening the purge valve, perform an actual purge operation to cause the filling pump and the discharge pump to return the treatment liquid from the discharge pump toward the filling pump through the return pipe in a state where the purge valve is opened and the inlet valve, the outlet valve, the first intermediate valve, and the second intermediate valve are closed.

3. The substrate processing apparatus according to claim 2, wherein
as the purge operation, the controller is configured to
after closing the inlet valve and before opening the purge valve, cause the discharge pump to start pushing the treatment liquid from the discharge pump toward the purge valve through the return pipe in a state where the outlet valve, the second intermediate valve, and the purge valve are closed, and
as the purge valve opening operation of the purge operation, the controller is configured to
open the purge valve in a state where the inlet valve, the outlet valve, the first intermediate valve, and the second intermediate valve are closed, after a preset time has elapsed since the start of pushing of the treatment liquid through the return pipe.

4. The substrate processing apparatus according to claim 2, wherein
as the purge operation, the controller is configured to
after closing the inlet valve and before opening the purge valve, cause the discharge pump to adjust the pressure of the treatment liquid in the discharge pump so that the pressure value measured by the discharge pressure sensor becomes a first purge pressure in a state where the outlet valve, the second intermediate valve, and the purge valve are closed,
as the purge valve opening operation of the purge operation, the controller is configured to
open the purge valve in a state where the inlet valve, the outlet valve, the first intermediate valve, and the second intermediate valve are closed, when the pressure value measured by the discharge pressure sensor reaches the first purge pressure,
as the purge operation, the controller is configured to
after opening the purge valve, cause the discharge pump to adjust the pressure of the treatment liquid in the discharge pump so that the pressure value measured by the discharge pressure sensor becomes a second purge pressure in a state where the inlet valve, the outlet valve, the first intermediate valve, and the second intermediate valve are closed, and
as the actual purge operation of the purge operation, the controller is configured to
when the pressure value measured by the discharge pressure sensor reaches the second purge pressure, cause the filling pump and the discharge pump to return the treatment liquid from the discharge pump toward the filling pump through the return pipe so that the pressure value measured by the discharge pressure sensor maintains the second purge pressure, in a state where the purge valve is opened, and the inlet valve, the outlet valve, the first intermediate valve, and the second intermediate valve are closed.

5. The substrate processing apparatus according to claim 1, wherein
the first intermediate valve, the second intermediate valve, and the filter are each disposed in the layer same as the first processing chamber or in the layer higher than the first processing chamber.

6. The substrate processing apparatus according to claim 2, wherein
the purge valve and the return position are each disposed in the layer same as the first processing chamber or in the layer higher than the first processing chamber.

7. The substrate processing apparatus according to claim 1, wherein
the filling pump includes
a first storage space configured to store the treatment liquid,
a first volume changing member configured to change a volume of the first storage space, and
a first pump drive mechanism configured to perform a pump operation by operating the first volume changing member,
the filling pressure sensor is configured to measure a pressure of the treatment liquid in the first storage space,
the discharge pump includes
a second storage space configured to store the treatment liquid,
a second volume changing member configured to change a volume of the second storage space, and
a second pump drive mechanism configured to perform a pump operation by operating the second volume changing member, and
the discharge pressure sensor is configured to measure the pressure of the treatment liquid in the second storage space.

8. A substrate processing apparatus configured to processes a substrate, comprising:
a plurality of processing chambers stacked in a vertical direction;
a liquid supply mechanism configured to supply a treatment liquid to at least one of the plurality of processing chambers; and
a controller, wherein
each of the plurality of processing chambers includes
a chuck configured to hold a substrate, and
a nozzle configured to discharge the treatment liquid to the substrate held by the chuck,
the liquid supply mechanism includes
a feed pipe configured to supply the treatment liquid to a first nozzle that is the nozzle of a first processing chamber among the plurality of processing chambers,
a filling pump provided in the feed pipe in a layer lower than the first processing chamber,
a discharge pump provided in the feed pipe between the filling pump and the first nozzle in a layer same as the first processing chamber or in a layer higher than the first processing chamber,
an inlet valve provided in the feed pipe at an upstream position of the filling pump,
an outlet valve provided in the feed pipe between the discharge pump and the first nozzle,
a first intermediate valve provided in the feed pipe between the filling pump and the discharge pump,
a return pipe configured to connect the discharge pump and a return position in the feed pipe between the first intermediate valve and the inlet valve, and
a purge valve provided in the return pipe,
the filling pump includes a filling pressure sensor configured to measure a pressure of the treatment liquid in the filling pump,
the discharge pump includes a discharge pressure sensor configured to measure a pressure of the treatment liquid in the discharge pump, and
as a purge operation, the controller is configured to
open the inlet valve in a state where the outlet valve, the first intermediate valve, and the purge valve are closed to release the treatment liquid in the filling pump to an upstream side of atmospheric pressure of the inlet valve,
close the inlet valve after a preset time has elapsed since the opening of the inlet valve so that a pressure value measured by the discharge pressure sensor does not become a negative pressure when the purge valve is opened,
after closing the inlet valve, perform a purge valve opening operation to open the purge valve in a state where the outlet valve and the first intermediate valve are closed, and
after opening the purge valve, perform an actual purge operation to cause the treatment liquid to be returned from the discharge pump toward the filling pump through the return pipe in a state where the outlet valve and the first intermediate valve are closed.

9. A method for controlling a substrate processing apparatus configured to processes a substrate,
the substrate processing apparatus including
a plurality of processing chambers stacked in a vertical direction, and
a liquid supply mechanism configured to supply a treatment liquid to at least one of the plurality of processing chambers,
each of the plurality of processing chambers including
a chuck configured to hold a substrate, and
a nozzle configured to discharge the treatment liquid to the substrate held by the chuck,
the liquid supply mechanism including
a feed pipe configured to supply the treatment liquid to a first nozzle that is the nozzle of a first processing chamber among the plurality of processing chambers,
a filling pump provided in the feed pipe in a layer lower than the first processing chamber,
a discharge pump provided in the feed pipe between the filling pump and the first nozzle in a layer same as the first processing chamber or in a layer higher than the first processing chamber,
an inlet valve provided in the feed pipe at an upstream position of the filling pump,
an outlet valve provided in the feed pipe between the discharge pump and the first nozzle,
a filter provided in the feed pipe between the filling pump and the discharge pump,
a first intermediate valve provided in the feed pipe between the filling pump and the filter, and
a second intermediate valve provided in the feed pipe between the filter and the discharge pump,
the filling pump including a filling pressure sensor configured to measure a pressure of the treatment liquid in the filling pump, and
the discharge pump including a discharge pressure sensor configured to measure a pressure of the treatment liquid in the discharge pump,
the method comprising:
as a pre-filtration operation,
causing the filling pump to adjust the pressure of the treatment liquid in the filling pump so that a pressure value measured by the filling pressure sensor becomes a first supply pressure in a state where the inlet valve, the outlet valve, the first intermediate valve, and the second intermediate valve are closed;
pushing the treatment liquid to the second intermediate valve by opening the first intermediate valve when the pressure value measured by the filling pressure sensor reaches the first supply pressure;
during a period from the opening of the first intermediate valve to opening of the second intermediate valve, causing the filling pump to adjust the pressure of the treatment liquid in the filling pump so that the pressure value measured by the filling pressure sensor becomes a second supply pressure in a state where the inlet valve and the second intermediate valve are closed;
after the first intermediate valve is opened, causing the discharge pump to adjust the pressure of the treatment liquid in the discharge pump so that a pressure value measured by the discharge pressure sensor becomes a third supply pressure in a state where the outlet valve and the second intermediate valve are closed; and
opening the second intermediate valve when the pressure value measured by the discharge pressure sensor reaches the third supply pressure, and
the method further comprising,
as an actual filtration operation after the pre-filtration operation,
causing the treatment liquid to be sent from the filling pump toward the discharge pump in a state where the inlet valve and the outlet valve are closed.

10. A method for controlling a substrate processing apparatus configured to processes a substrate,
the substrate processing apparatus including
a plurality of processing chambers stacked in a vertical direction, and
a liquid supply mechanism configured to supply a treatment liquid to at least one of the plurality of processing chambers,
each of the plurality of processing chambers including
a chuck configured to hold a substrate, and
a nozzle configured to discharge the treatment liquid to the substrate held by the chuck,
the liquid supply mechanism including
a feed pipe configured to supply the treatment liquid to a first nozzle that is the nozzle of a first processing chamber among the plurality of processing chambers,
a filling pump provided in the feed pipe in a layer lower than the first processing chamber,
a discharge pump provided in the feed pipe between the filling pump and the first nozzle in a layer same as the first processing chamber or in a layer higher than the first processing chamber,
an inlet valve provided in the feed pipe at an upstream position of the filling pump,
an outlet valve provided in the feed pipe between the discharge pump and the first nozzle,
a first intermediate valve provided in the feed pipe between the filling pump and the discharge pump,
a return pipe configured to connect the discharge pump and a return position in the feed pipe between the first intermediate valve and the inlet valve, and
a purge valve provided in the return pipe,
the filling pump including a filling pressure sensor configured to measure a pressure of the treatment liquid in the filling pump, and
the discharge pump including a discharge pressure sensor configured to measure a pressure of the treatment liquid in the discharge pump,
the method comprising: as a purge operation,
opening the inlet valve in a state where the outlet valve, the first intermediate valve, and the purge valve are closed to release the treatment liquid in the filling pump to an upstream side of atmospheric pressure of the inlet valve;
closing the inlet valve after a preset time has elapsed since the opening of the inlet valve so that a pressure value measured by the discharge pressure sensor does not become a negative pressure when the purge valve is opened;
after closing the inlet valve, performing a purge valve opening operation to open the purge valve in a state where the outlet valve and the first intermediate valve are closed; and
after opening the purge valve, performing an actual purge operation to cause the treatment liquid to be returned from the discharge pump toward the filling pump through the return pipe in a state where the outlet valve and the first intermediate valve are closed.
